(19) United States
(12) Patent Application Publication
(10) Pub. No.: US 2026/0036630 A1
(43) Pub. Date: Feb. 5, 2026

(54) BATTERY MANAGEMENT DEVICE AND METHOD

(71) Applicant: BATTLAB INC., Ansan-si (KR)

(72) Inventor: Chul Hyun SIN, Incheon (KR)

(73) Assignee: BATTLAB INC., Ansan-si (KR)

(21) Appl. No.: 18/984,839

(22) Filed: Dec. 17, 2024

(30) Foreign Application Priority Data
Aug. 5, 2024 (KR) 10-2024-0103802
Aug. 5, 2024 (KR) 10-2024-0103804
Aug. 5, 2024 (KR) 10-2024-0103805

(51) Int. Cl. G01R 31/367; G01R 31/374; G01R 31/389

(52) U.S. Cl. CPC G01R 31/367; G01R 31/374; G01R 31/389

(57) ABSTRACT

The present disclosure relates to a battery management device and method, particularly to a technique of estimating and optimizing battery state using frequency-band-specific impedance data, wherein the battery management device includes: an impedance measurement unit configured to measure frequency-band-specific impedance data of a battery; and a controller configured to acquire the frequency-band-specific impedance data measured by the impedance measurement unit, generate a graph representing the battery's impedance characteristics based on the impedance data, select a first equivalent circuit model among a plurality of predefined equivalent circuit models based on the graph, and estimate the battery state based on the selected first equivalent circuit model.

### CROSS-REFERENCE TO RELATED APPLICATIONS

This application claims priority to and the benefit of Korean Patent Application Nos. 10-2024-0103802, 10-2024-0103804, and 10-2024-0103805, all filed on Aug. 5, 2024, the disclosures of which are incorporated herein by reference in their entirety.

### BACKGROUND

The present disclosure relates to a battery management device and method, and more particularly, to a technique for estimating the internal temperature of a battery.

With the rapid increase in usage of various electronic devices such as electric vehicles, smartphones, and notebook computers, the importance of batteries has grown substantially. Lithium-ion batteries, due to their high energy density and long lifespan, are widely employed in numerous electronic devices. However, accurately diagnosing and managing the condition of a battery remains a significant challenge. If the battery's state is not accurately identified, unexpected shutdowns or performance degradation may occur, causing inconvenience to users and, in severe cases, leading to safety issues.

Battery state diagnostic technologies consider various parameters, such as State of Charge (SOC), State of Health (SOH), internal temperature estimation, internal resistance estimation, and fault diagnosis. These diagnostics are generally performed based on battery measurement data and computed through various algorithms and methodologies. For example, SOC estimation is frequently done using the coulomb counting method or an Extended Kalman Filter (EKF).

A Battery Management System (BMS) traditionally employs direct current (DC) data, such as cell voltage, current, and surface temperature, to diagnose battery states. However, these methods have limitations in fully reflecting the complex electrochemical characteristics of the battery. Recently, diagnostic technologies using alternating current (AC) data, particularly those applying Electrochemical Impedance Spectroscopy (EIS), have been actively researched.

EKF is a method for estimating SOC using state and measurement equations of the battery, correcting errors through iterative prediction and update steps. However, the performance of the EKF can vary depending on the accuracy of the Equivalent Circuit Model (ECM) parameters and whether battery aging is considered. Additionally, temperature changes can affect its accuracy.

Conventional BMSs generally determine ECM parameters based solely on charge and discharge data, making it difficult to adequately reflect changes due to battery aging.

The above-described background technologies reflect knowledge possessed or acquired by the inventor in conceiving the present disclosure. It should not be assumed that all of this technology was publicly disclosed prior to this application.

### SUMMARY

According to an embodiment of the present disclosure, A battery management device according to one embodiment of the present disclosure for achieving the above-described objectives may comprise: an impedance measurement unit configured to measure impedance data of a battery for each frequency band; and a controller configured to acquire the frequency-band-specific impedance data measured by the impedance measurement unit, generate a graph representing the impedance characteristics of the battery based on the impedance data, select a first equivalent circuit model among multiple predefined equivalent circuit models based on the graph representing the impedance characteristics, and estimate the battery state based on the selected first equivalent circuit model.

The controller may compare the graph representing the impedance characteristics and a graph representing characteristics of the first equivalent circuit model to generate an error index for the equivalent circuit model, and if the error index exceeds a preset threshold, select a second equivalent circuit model among the multiple predefined equivalent circuit models.

If the error index is equal to or below the preset threshold, the controller may determine parameters of the first equivalent circuit model.

The error index may include at least one of the variance of parameter values according to temperature at each SOC level, mean absolute error (MAE), mean squared error (MSE), root mean squared error (RMSE), and R-squared value.

The graph representing the impedance characteristics may be a Nyquist plot.

The controller may determine the parameters of the first equivalent circuit model by using a curve fitting method.

The curve fitting method may employ the Levenberg-Marquardt algorithm.

The controller may generate a graph representing the impedance characteristics for each internal temperature range of the battery based on the impedance data and, based on the graph representing the impedance characteristics, select a third equivalent circuit model among the multiple predefined equivalent circuit models for each internal temperature range of the battery, and estimate the battery state based on the selected third equivalent circuit model.

The battery management device may further comprise a communication unit for transmitting and receiving data, and the controller may send a request message regarding the multiple predefined equivalent circuit models to a server, receive a response message corresponding to the request message from the server, and thereby obtain the multiple predefined equivalent circuit models.

The battery management device may further comprise a battery state measurement unit, and the controller may estimate the SOC based on data measured by the battery state measurement unit, generate a graph representing the impedance characteristics for each estimated SOC range, and, based on the graph representing the impedance characteristics, select a third equivalent circuit model among the multiple predefined equivalent circuit models for each SOC range of the battery, and estimate the battery state based on the selected third equivalent circuit model.

The controller may update the equivalent circuit model for each SOC range based on at least one of the usage time of the battery and the number of charge/discharge cycles.

A battery pack according to one embodiment of the present disclosure for achieving the above-described objectives may comprise: a battery module including a plurality of battery cells; and a battery management device. The battery management device may comprise an impedance measurement unit configured to measure impedance data for each frequency band of each battery cell; and a controller configured to acquire the frequency-band-specific impedance data measured by the impedance measurement unit, generate a graph representing the impedance characteristics per internal temperature range of each battery cell based on the impedance data of each battery cell, and, based on the graph representing the impedance characteristics, select a first equivalent circuit model among multiple predefined equivalent circuit models for each of the internal temperature ranges, and estimate the battery state based on the selected first equivalent circuit model.

According to one embodiment of the present disclosure for achieving the above object, a battery management device may comprise: an impedance measurement unit configured to measure impedance data of the battery for each frequency band; and a controller configured to acquire the frequency-band-specific impedance data measured by the impedance measurement unit, generate a graph representing the battery's impedance characteristics based on the impedance data, identify whether the graph representing the impedance characteristics has an x-intercept, and if the graph is of a type having no X-intercept, calculate a slope of the graph in a specific frequency band, and estimate the internal temperature of the battery using a first trained model that has learned the correlation between the slope and the internal temperature.

The slope calculation unit may select, as the specific frequency band, a frequency band that minimizes the correlation between SOC (State of Charge) and the slope, and also minimizes an error index of the first trained model, thereby calculating the slope.

The first trained model may be a model trained using a training dataset including the slope of the graph in the specific frequency band and the internal temperature.

The controller may use a polynomial regression model to estimate the internal temperature, and the order of the polynomial regression model may be determined through performance evaluation.

The graph representing the impedance characteristics may be a Nyquist plot.

If the graph representing the impedance characteristics is of a type having an X-intercept, the controller may calculate the X-intercept value and estimate the internal temperature using a second trained model that has learned the correlation between the X-intercept value and the internal temperature.

The controller may identify a first frequency and a second frequency at which the sign of the imaginary part of the impedance changes, derive a first-order linear equation using real and imaginary parts of the impedance corresponding to these two frequencies, and calculate the X-intercept value using the first-order linear equation.

The controller may divide the entire frequency range into multiple sections, measure impedance at the representative frequency of each section to identify a section where the sign of the imaginary part changes, and then perform measurements within that section to identify the first and second frequencies.

According to another embodiment, a battery pack comprising a battery module having a battery channel including multiple battery cells, and a battery management device, may be provided. The battery management device may comprise: an impedance measurement unit configured to measure impedance data of each battery cell for each frequency band; and a controller configured to acquire the frequency-band-specific impedance data measured by the impedance measurement unit for each battery channel, generate a graph representing the impedance characteristics of the battery based on the impedance data, identify whether the graph representing the impedance characteristics has an x-intercept, and if the graph is of a type having no X-intercept, calculate the slope of the graph in a specific frequency band, and estimate the internal temperature of the battery using a first trained model that has learned the correlation between the slope and the internal temperature.

A battery management method according to another embodiment may include: measuring impedance data for each frequency band; obtaining the measured frequency-band-specific impedance data; generating a graph representing the impedance characteristics of the battery based on the obtained impedance data; identifying the type of the generated graph and determining whether an X-intercept exists; if the graph is of a type having no X-intercept, calculating the slope of the graph in a specific frequency band; and estimating the internal temperature of the battery using a first trained model that has learned the correlation between the slope and the internal temperature.

If the graph is of a type having an X-intercept, the method may further comprise calculating the X-intercept value and estimating the internal temperature using a second trained model that has learned the correlation between the X-intercept value and the internal temperature.

A battery management device according to one embodiment of the present disclosure, for achieving the above-described object, may include: an impedance measurement unit configured to measure impedance parameters of the battery for each frequency band; and a controller configured to control the impedance measurement unit to apply signals of a specific frequency band to the battery, receive impedance parameters corresponding to the specific frequency band from the impedance measurement unit, and input the impedance parameters into a first learning model to estimate the internal temperature of the battery.

The first learning model may be an Arrhenius linear equation-based regression model generated based on a dataset including impedance parameters and internal temperatures of the battery.

The specific frequency band may be selected to minimize the correlation between the frequency-band-specific impedance and the State of Charge (SOC).

The specific frequency band may be a frequency band that minimizes the correlation between the frequency-band-specific impedance and the SOC, and also minimizes the error index of the first learning model.

The impedance parameters may include at least one of a real part, an imaginary part, a magnitude, and a phase.

If the internal temperature of the battery estimated by the first learning model exceeds a critical temperature, the controller may re-estimate the internal temperature by inputting the impedance parameters into a second learning model. If the internal temperature estimated by the first learning model is below the critical temperature, the controller may re-estimate the internal temperature by inputting the impedance parameters into a third learning model.

The critical temperature may be a temperature at which the slope according to the Arrhenius linear equation between the impedance parameters and the internal temperature is distinguished.

The second learning model may be generated based on a dataset including impedance parameters and battery internal temperatures above the critical temperature, and the third learning model may be generated based on a dataset including impedance parameters and battery internal temperatures below the critical temperature.

A battery pack according to one embodiment of the present disclosure for achieving the above-described object may include: a battery module having a battery channel including a plurality of battery cells; and the battery management device. The battery management device may include an impedance measurement unit configured to measure frequency-band-specific impedance data of each battery cell; and a controller configured, for each battery channel, to control the impedance measurement unit to apply signals of a specific frequency band to the battery, receive impedance parameters corresponding to the specific frequency band from the impedance measurement unit, input the impedance parameters into a first learning model, and estimate the internal temperature of the battery.

A battery management method according to one embodiment of the present disclosure for achieving the above-described object may include: controlling application of signals of a specific frequency band to the battery; receiving impedance parameters corresponding to the specific frequency band; and inputting the impedance parameters into a first learning model to estimate the internal temperature of the battery. The specific frequency band may minimize the correlation between frequency-band-specific impedance and the State of Charge (SOC).

### BRIEF DESCRIPTION OF THE DRAWINGS

FIG. 1a is a schematic diagram illustrating a management system according to one embodiment of the present disclosure.

FIG. 1b is a schematic diagram illustrating the configuration of a battery management device according to one embodiment of the present disclosure.

FIG. 1c is a schematic diagram illustrating a battery pack according to one embodiment of the present disclosure.

FIG. 1d is a schematic diagram illustrating a battery module according to one embodiment of the present disclosure.

FIG. 1e is a flowchart illustrating a battery state estimation operation of the battery management device according to one embodiment of the present disclosure.

FIG. 1f is a flowchart illustrating an equivalent circuit model selection operation of the battery management device according to one embodiment of the present disclosure.

FIG. 1g is a diagram comparing the first equivalent circuit model and a graph representing impedance characteristics at −10° C. according to one embodiment of the present disclosure.

FIG. 1h is a diagram comparing the second equivalent circuit model and a graph representing impedance characteristics at −10° C. according to one embodiment of the present disclosure.

FIG. 1i is a diagram comparing a first parameter set of the first equivalent circuit model and a graph representing impedance characteristics according to one embodiment of the present disclosure.

FIG. 1j is a diagram comparing a second parameter set of the first equivalent circuit model and a graph representing impedance characteristics according to one embodiment of the present disclosure.

FIG. 1k is a diagram showing the distribution of temperature-dependent parameters according to SOC for the first equivalent circuit model determined by the battery management device according to one embodiment of the present disclosure.

FIG. 1l is a diagram showing the distribution of temperature-dependent parameters according to SOC for the second equivalent circuit model determined by the battery management device according to one embodiment of the present disclosure.

FIG. 1m is a diagram comparing model-based estimated voltage values with terminal voltages according to SOC for the models determined by the battery management device according to one embodiment of the present disclosure.

FIG. 2a is a schematic diagram of a management system according to one embodiment of the present disclosure.

FIG. 2b is a schematic diagram of the configuration of a battery management device according to one embodiment of the present disclosure.

FIG. 2c is a schematic diagram of a battery pack according to one embodiment of the present disclosure.

FIG. 2d is a schematic diagram of a battery module according to one embodiment of the present disclosure.

FIG. 2e is a flowchart illustrating the operation of estimating the internal temperature of a battery by the battery management device according to one embodiment of the present disclosure.

FIG. 2f is a flowchart illustrating the operation of selecting a specific frequency band by the battery management device according to one embodiment of the present disclosure.

FIG. 2g is a flowchart illustrating the operation of calculating the X-intercept value by the battery management device according to one embodiment of the present disclosure.

FIG. 2h is a diagram showing a graph representing the impedance characteristics at a first SOC of a first battery channel according to one embodiment of the present disclosure.

FIG. 2i is a diagram showing a graph representing the impedance characteristics at a second SOC of the first battery channel according to one embodiment of the present disclosure.

FIG. 2j is a diagram showing a graph representing the impedance characteristics at a third SOC of the first battery channel according to one embodiment of the present disclosure.

FIG. 2k is a diagram showing a graph representing the impedance characteristics at a first SOC of the first battery channel in a specific frequency band according to one embodiment of the present disclosure.

FIG. 2l is a diagram showing a graph representing the impedance characteristics at a second SOC of the first battery channel in the specific frequency band according to one embodiment of the present disclosure.

FIG. 2m is a diagram showing a graph representing the impedance characteristics at a third SOC of the first battery channel in the specific frequency band according to one embodiment of the present disclosure.

FIG. 2n is a diagram showing a graph representing the impedance characteristics at a first SOC of a second battery channel according to one embodiment of the present disclosure.

FIG. 2o is a diagram showing a graph representing the impedance characteristics at a second SOC of the second battery channel according to one embodiment of the present disclosure.

FIG. 2p is a diagram showing a graph representing the impedance characteristics at a third SOC of the second battery channel according to one embodiment of the present disclosure.

FIG. 3a is a schematic diagram of a management system according to one embodiment of the present disclosure.

FIG. 3b is a schematic diagram illustrating the configuration of a battery management device according to one embodiment of the present disclosure.

FIG. 3c is a schematic diagram illustrating a battery pack according to one embodiment of the present disclosure.

FIG. 3d is a schematic diagram illustrating a battery module according to one embodiment of the present disclosure.

FIG. 3e is a flowchart showing a battery internal temperature estimation operation of the battery management device according to one embodiment of the present disclosure.

FIG. 3f is a flowchart showing an operation of determining a critical temperature by the battery management device according to one embodiment of the present disclosure.

FIG. 3g is a diagram showing the real part of the impedance according to temperature for each SOC according to one embodiment of the present disclosure.

FIG. 3h is a diagram showing the impedance magnitude according to temperature for each SOC according to one embodiment of the present disclosure.

FIG. 3i is a diagram showing the imaginary part of the impedance according to temperature for each SOC according to one embodiment of the present disclosure.

FIG. 3j is a diagram showing the impedance phase according to temperature for each SOC according to one embodiment of the present disclosure.

FIG. 3k is a diagram showing the temperature according to the real part of the impedance for each SOC based on the Arrhenius linear equation of the battery management device according to one embodiment of the present disclosure.

### DETAILED DESCRIPTION

The present disclosure may be variously modified and may have various embodiments. Specific embodiments are illustrated in the drawings and described in detail in the specification. The effects and characteristics of the present disclosure, and the methods of achieving them, will become apparent with reference to the embodiments described below. However, the present disclosure is not limited to the embodiments disclosed herein; it can be implemented in various forms.

Each logic block may be a module, segment, or a portion of code including one or more executable instructions for performing a specific logical function. In one embodiment, the operations mentioned for each block may be performed in a different order than described. For example, two blocks shown in sequence may be performed substantially simultaneously, or in reverse order depending on conditions or the environment. Unless clearly indicated otherwise, singular terms may include the plural.

Terms such as “include” or “have” as used herein indicate that certain features or elements exist, but do not exclude the possibility of adding one or more other features or elements.

Instructions executed by a processor in a computer or other programmable data processing equipment can constitute means for performing the functions described with reference to the flowcharts or block diagrams. The instructions, loaded in a computer, can create processes that are executed on a computer to perform a series of steps.

As used herein, the term “unit” may mean a component that performs a specific function via software or hardware (such as FPGA or ASIC). The “unit” is not limited to software or hardware; it may exist as data stored on an addressable storage medium, and one or more processors may be configured to execute a certain function.

In the drawings, for convenience of explanation, component sizes may be exaggerated or reduced. The sizes and thicknesses represented are arbitrary and do not limit the present disclosure. Also, conditions described as “exceeding,” “less than,” etc. may alternatively be expressed as “greater than,” “no less than,” or “no more than,” and are not intended to exclude other conditions.

The terms “first,” “second,” etc., may be used to distinguish various elements, but such terms should not limit the components. They are used only for distinction purposes.

Software may include a computer program, code, instructions, or combinations thereof and can configure or direct a processing apparatus. Software and/or data may be embodied permanently or temporarily in various means, including machine-type devices or signal waves. Software may be distributed over networked computer systems and stored or executed in a distributed manner. Software and data can be stored in one or more computer-readable recording media.

A battery according to the present disclosure is not limited to a particular type and may indicate one or more batteries. The battery may include battery cells, battery modules, battery racks, and battery packs. Accordingly, the battery management device according to the present disclosure can estimate the internal temperature for battery cells, modules, racks, and packs.

The internal temperature of a battery as per the present disclosure refers to the temperature inside the battery, for example, the temperature of the electrolyte inside a lithium-ion battery. This internal temperature may be obtained through temperature estimation or sensor data.

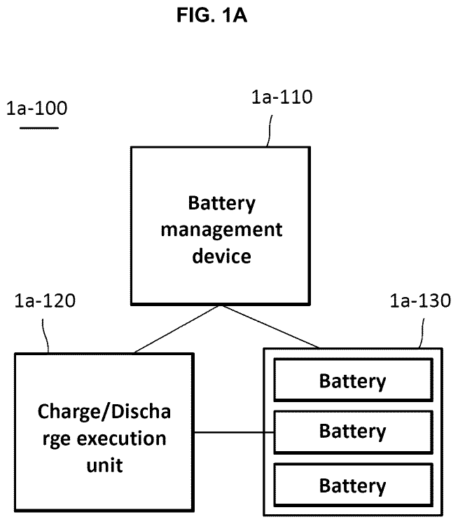

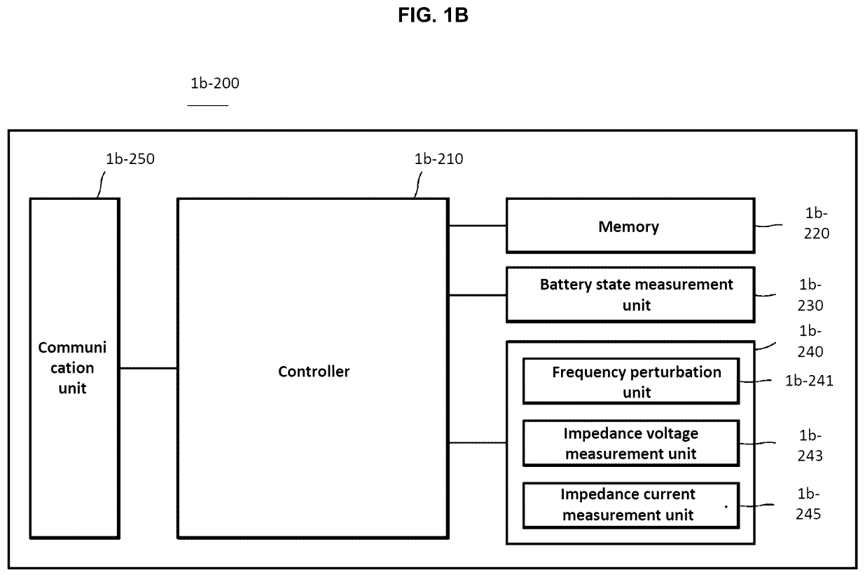

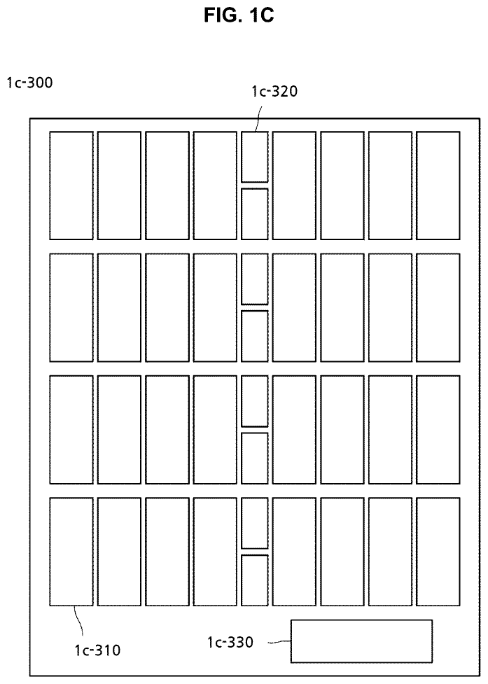

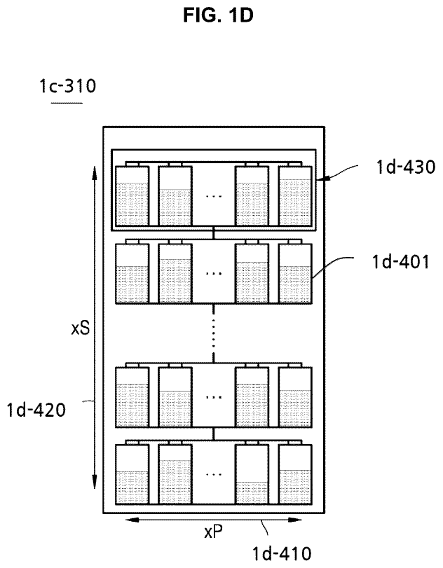

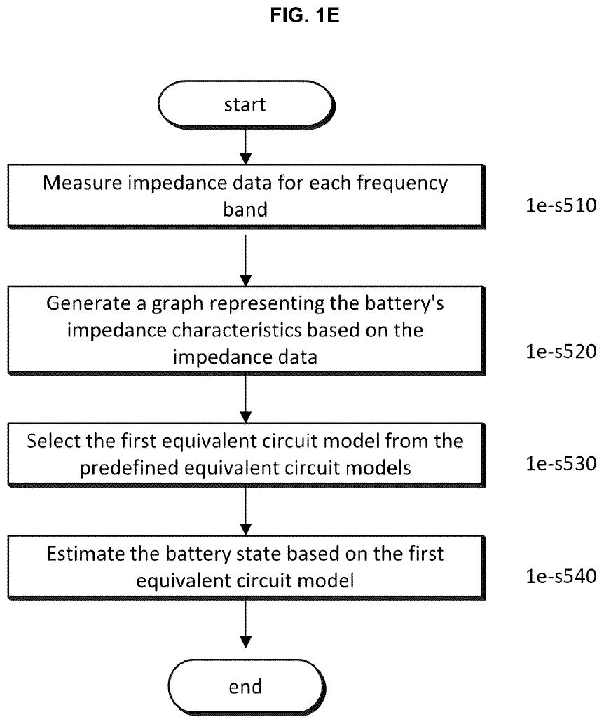

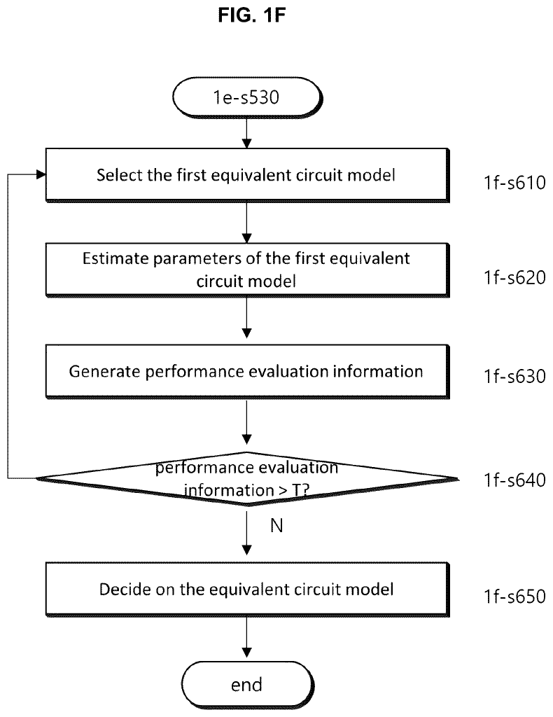

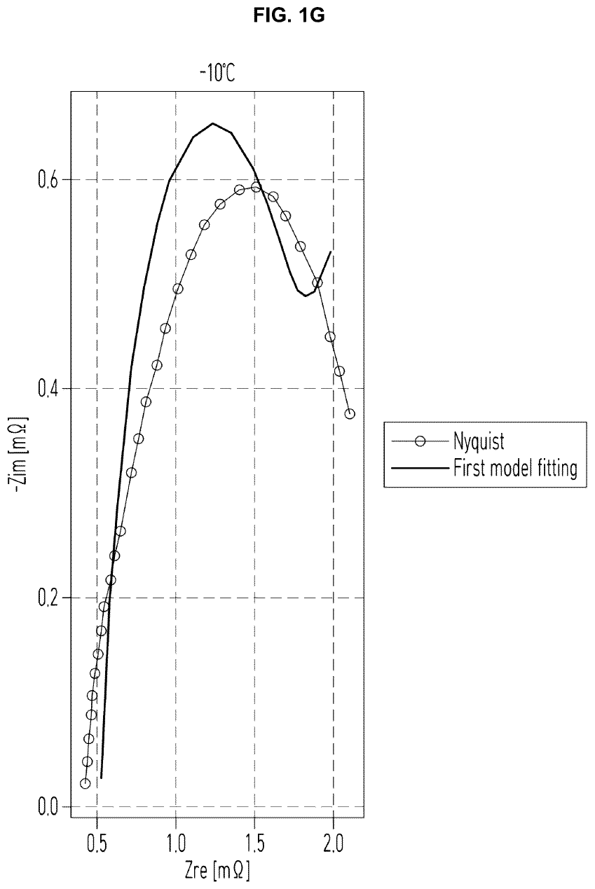

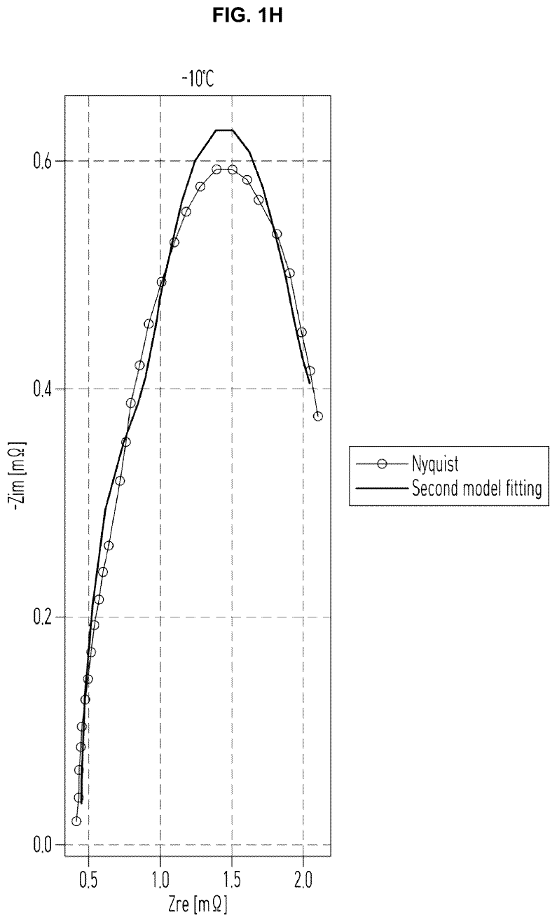

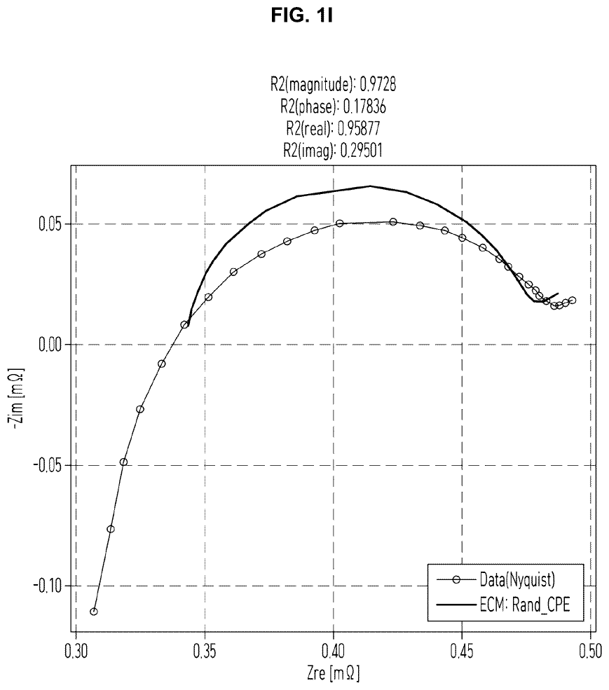

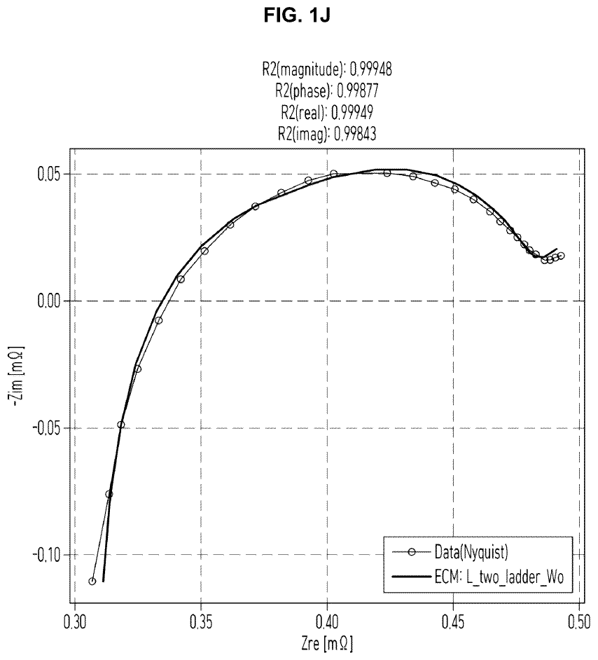

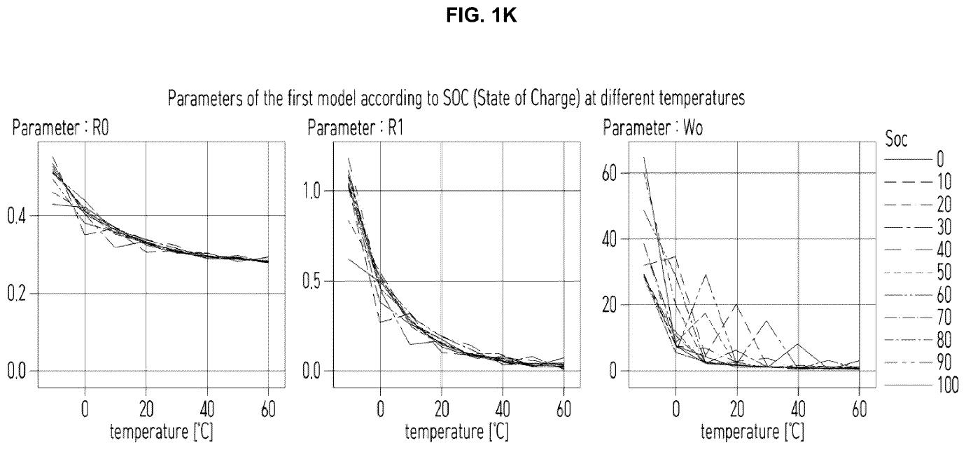

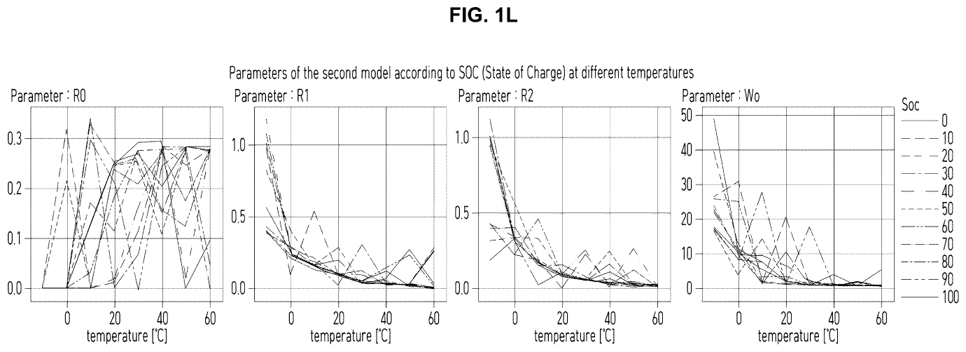

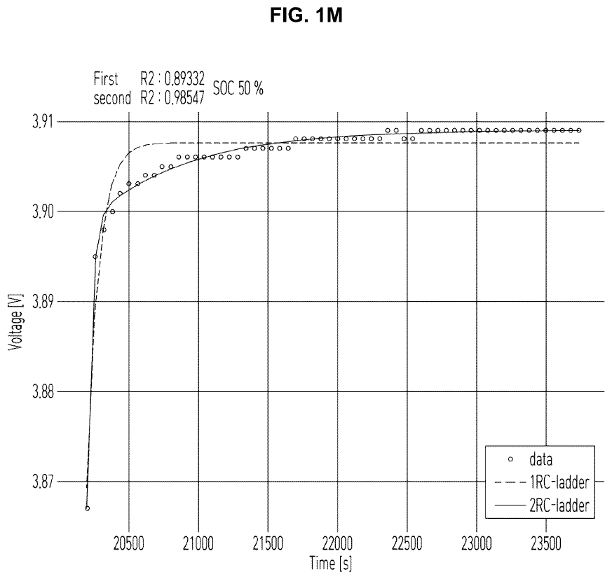

FIG. 1a is a diagram schematically illustrating a management system (1a-100) according to an embodiment of the present disclosure. Referring to FIG. 1a, the management system (1a-100) may include a Battery management system (BMS, Battery Management System) (1a-110), a Charge/Discharge execution unit (1a-120), and a plurality of batteries (1a-130).

The plurality of batteries (1a-130) are devices subjected to internal temperature and fire prediction, can be connected to the Charge/Discharge execution unit (1a-120) to be charged or discharged, and can be managed by being connected to the Battery management device (1a-110).

The Charge/Discharge execution unit (1a-120), controlled by the Battery management device (1a-110), can perform charging or discharging with respect to the connected battery (1a-130).

The Battery management device (1a-110) is a device that controls battery charging and discharging, and can perform operations such as battery State of Charge (SOC) and battery state monitoring. Specifically, the Battery management device (1a-110) can perform current measurement of the battery (1a-130) mounted on an Energy Storage System (ESS) or an electric vehicle (BEV), cell voltage measurement, surface temperature measurement, SOC calculation, cell balancing, relay or FET control, fault diagnosis, fire prediction, and so forth.

According to an embodiment of the present disclosure, the Battery management device (1a-110) can estimate the internal temperature of the battery (1a-130), and perform fire diagnosis and fire management. Such a Battery management device (1a-110) can perform an operation according to an embodiment of the present disclosure. Hereinafter, the Battery management device (1a-110) will be described in detail with reference to FIG. 1b.

The management system (1a-100) according to one embodiment of the present disclosure may include a separate server (not shown). For example, the server may include a plurality of set equivalent circuit models, and the Battery management device (1a-110) may transmit information on the impedance of the battery (1a-130) to the server and receive information on the internal temperature of the battery from the server in order to manage the battery (1a-130).

FIG. 1b is a diagram schematically illustrating the configuration (200) of the Battery management device (1a-110) according to an embodiment of the present disclosure. Referring to FIG. 1b, the Battery management device (1a-110) is illustrated as being configured by a Controller (1b-210), a Memory (1b-220), a Battery state measurement unit (1b-230), an Impedance measurement unit (1b-240), and a Communication unit (1b-250), but is not necessarily limited thereto. For example, each of the Controller (1b-210), Memory (1b-220), Battery state measurement unit (1b-230), Impedance measurement unit (1b-240), and Communication unit (1b-250) may exist as a physically independent single component.

The Memory (1b-220) can store various data for the overall operation of the Battery management device (1a-110), such as programs for processing or control by the Controller (1b-210) in the Battery management device (1a-110). The Memory (1b-220) can store a plurality of application programs running, data for operation of the Battery management device (1a-110), and instructions. The Memory (1b-220) can be implemented as an internal memory such as ROM or RAM included in the Controller (1b-210), or as a memory separate from the Controller (1b-210).

According to one embodiment, the Memory (1b-220) can store a plurality of set equivalent circuit models, current of the battery (1a-130), cell voltage, surface temperature, SOC, and so forth. The Memory (1b-220) can be implemented as an internal memory included in the Controller (1b-210) or a separate external memory.

The Battery state measurement unit (1b-230) can measure the voltage of a battery cell, cell balancing, and the surface temperature of the battery cell. The Battery state measurement unit (1b-230) can measure voltage of the battery cell, cell balancing, internal temperature, and surface temperature, and deliver that data to the Controller (1b-210).

The Impedance measurement unit (1b-240) can measure the impedance of the battery in each frequency band. The Impedance measurement unit (1b-240) can be implemented as a Frequency perturbation unit (1b-241), an Impedance voltage measurement unit (1b-243), and an Impedance current measurement unit (1b-245). The Impedance measurement unit (1b-240) can measure the impedance of the battery by using Electrical Impedance Spectroscopy (EIS). Specifically, the Impedance measurement unit (1b-240) applies infinitesimal sinusoidal current and voltage signals from the high-frequency region to the low-frequency region and can analyze impedance by measuring amplitude and phase changes from the response of the impedance voltage and impedance current signals within a range that does not deviate from the battery's electrical and thermal equilibrium states. The Impedance measurement unit (1b-240) can apply the frequency band instructed by the Controller (1b-210) to the battery (1a-130) to analyze the impedance and deliver at least one of impedance voltage, impedance current, and impedance to the Controller (1b-210). The measurement unit can extract necessary signals through passive and active filters for the impedance voltage and current. The filtering function of the measurement unit can be composed of ICs, OPAMPs, and RLC components, or can be implemented by an MCU and RLC components. After filtering, the signals can be delivered to the analog-to-digital converter (ADC) of the Controller.

The Frequency perturbation unit (1b-241) can apply a frequency signal to the battery to measure the battery's impedance in each frequency band. The Frequency perturbation unit (1b-241) can apply sinusoidal current and voltage signals related to the frequency band instructed by the Controller (1b-210).

The Impedance voltage measurement unit (1b-243) can measure the impedance voltage of the battery perturbed by the Frequency perturbation unit (1b-241). The Impedance voltage measurement unit (1b-243) can measure the voltage applied to the battery by the signal applied by the Frequency perturbation unit (1b-241).

The Impedance current measurement unit (1b-245) can measure the impedance current of the battery perturbed by the Frequency perturbation unit (1b-241). The Impedance current measurement unit (1b-245) can measure the current flowing in the battery due to the signal applied by the Frequency perturbation unit (1b-241).

The Communication unit (1b-250) performs functions for transmitting and receiving signals through a network. All or part of the Communication unit (1b-250) may be referred to as a transmitter, a receiver, or a transceiver. The Communication unit (1b-250) can provide functions for communication between the Battery management device (1a-110) and at least one other node through a communication network. According to one embodiment of the present disclosure, when a request signal is generated according to program code stored in a storage device, such as the Memory (1b-220) of the Battery management device (1a-110), the request signal can be transmitted to at least one other node via the communication network under control of the Communication unit (1b-250). Conversely, control signals or commands, content, files, etc., provided under the control of a processor of at least one other node can be received by the Battery management device (1a-110) through the Communication unit (1b-250). According to one embodiment, the Communication unit (1b-250) can transmit impedance information to the server and receive internal temperature information of the battery from the server. In addition, according to one embodiment, the Communication unit (1b-250) can transmit and receive a plurality of set equivalent circuit models from the server. The Battery management device (1a-110) can acquire various set equivalent circuit models through the Communication unit (1b-250).

The Controller (1b-210) may be a configuration for overall control of the Battery management device (1a-110). Specifically, the Controller (1b-210) can control the operation of the Battery management device (1a-110) by using various programs stored in the Memory (1b-220) of the Battery management device (1a-110). The Controller (1b-210) can include a CPU, RAM, ROM, a system bus, and the like. The Controller (1b-210) can be implemented as a single CPU or multiple CPUs (or DSPs, SOCs). In one embodiment, the Controller (1b-210) can be implemented as a digital signal processor (DSP), a microprocessor, or a TCON (Time controller). However, it is not limited thereto, and may include or be defined by one or more of a CPU (Central Processing Unit), MCU (Micro Controller Unit), MPU (Micro Processing Unit), controller, application processor (AP), communication processor (CP), or an ARM processor. The Controller (1b-210) can also be implemented as an SOC (System on Chip) or LSI (Large Scale Integration) with a built-in processing algorithm, or in the form of an FPGA (Field Programmable Gate Array).

According to one embodiment, the Controller (1b-210) can obtain impedance data for each frequency band of the battery from the Impedance measurement unit (1b-240). The Controller (1b-210) and the Impedance measurement unit (1b-240) are directly connected by a data bus, so that the measured impedance data can be received in real time. The impedance data is classified by frequency and includes real and imaginary parts of the impedance for each frequency. The Controller (1b-210) can temporarily store the received data in its internal memory or store it long-term in the Memory (1b-220).

The Controller (1b-210) can generate a graph representing the impedance characteristics of the battery based on the acquired impedance data. This graph is mainly generated in the form of a Nyquist plot. When creating a Nyquist plot, the Controller (1b-210) plots the real part of the impedance on the x-axis and the negative value of the imaginary part on the y-axis. The Controller (1b-210) can create a smooth curve between measured points using spline interpolation, and mark major frequency points to facilitate user identification.

According to one embodiment, the Controller (1b-210) can select a first equivalent circuit model among a plurality of set equivalent circuit models based on the generated impedance characteristic graph. The Controller (1b-210) loads a plurality of set equivalent circuit models stored in the Memory (1b-220) and generates a theoretical Nyquist plot for each equivalent circuit model. The Controller (1b-210) calculates the error between the generated theoretical plot and the actually measured impedance characteristic graph using the least squares method. The equivalent circuit model with the smallest error is selected as the first equivalent circuit model.

The Controller (1b-210) can estimate the battery state based on the selected first equivalent circuit model. The Controller (1b-210) sets initial values for each element of the selected equivalent circuit model and optimizes the model's parameters using the Levenberg-Marquardt algorithm. In the optimization process, the Controller (1b-210) calculates the model's impedance with the current parameter values and calculates the error between the calculated impedance and the measured impedance. The Controller (1b-210) calculates the Jacobian matrix to determine the parameter update direction and adjusts the damping factor to control the convergence speed and stability. This process can be repeated until the convergence condition is met.

Using the optimized parameter values, the Controller (1b-210) estimates the state of the battery. For example, the ohmic resistance value is used to estimate the internal resistance of the battery, the charge transfer resistance value is used to estimate the degree of battery aging, and the double-layer capacitance value is used to estimate the effective surface area of the battery.

According to one embodiment, the Controller (1b-210) can generate an error indicator of the equivalent circuit model by comparing the graph representing impedance characteristics and the graph representing the characteristics of the first equivalent circuit model. The Controller (1b-210) calculates performance indicators such as SOC-based parameter variance by temperature, mean absolute error (MAE), mean squared error (MSE), root mean squared error (RMSE), and R-squared values between the measured impedance data and the impedance data predicted by the model. In addition, to calculate the parameter variance by temperature at each SOC, the Controller (1b-210) performs impedance measurements at various SOC levels and temperatures, estimates model parameters under each condition, and calculates the standard deviation of the parameter values to find the variance.

If the generated error indicator exceeds a predetermined threshold, the Controller (1b-210) can select a second equivalent circuit model from the plurality of set equivalent circuit models. For each error indicator, the Controller (1b-210) applies weights to calculate a comprehensive score and checks whether the comprehensive score exceeds the predetermined threshold. If it exceeds the threshold, the Controller (1b-210) repeats the selection process among the remaining equivalent circuit models and selects a new model (the second equivalent circuit model). Then the battery state estimation process is performed again using the newly selected model.

According to one embodiment, the Controller (1b-210) can determine parameters of the selected equivalent circuit model using a curve fitting method. The Levenberg-Marquardt algorithm is used to perform curve fitting. The Controller (1b-210) sets initial parameter values, calculates the model's impedance response with the current parameter values, calculates the error between the measured impedance and the model impedance, and calculates the Jacobian matrix. The Controller (1b-210) forms the Levenberg-Marquardt equation and obtains a solution to update the parameters. The Controller (1b-210) adjusts the damping factor depending on whether the error decreases and repeats this process until the convergence condition is met.

Through this process, the Controller (1b-210) can analyze the impedance characteristics of the battery and select an appropriate equivalent circuit model to estimate the state of the battery.

The Controller (1b-210) can estimate the battery's State of Charge (SOC). For example, the Controller (1b-210) can estimate the battery's SOC based on the cell's voltage, cell balancing, and the battery's surface temperature delivered from the Battery state measurement unit (1b-230). For example, the Controller (1b-210) can estimate the battery's SOC through a coulomb counting method or estimate various states of the battery using an extended Kalman filter.

According to one embodiment, the Controller (1b-210) can control the Impedance measurement unit (1b-240) to apply signals of a frequency band to the battery. The Controller (1b-210) can receive impedance voltage and impedance current from the Impedance measurement unit (1b-240) and calculate impedance using the principle of a digital lock-in amplifier. In addition, the Controller (1b-210) can receive impedance from the Impedance measurement unit (1b-240). The impedance can be represented by real and imaginary parts, and the Controller (1b-210) can calculate the magnitude and phase of the impedance. Furthermore, the Controller (1b-210) can transmit and receive the impedance voltage and impedance current values to and from an external server or cloud via the Communication unit (1b-250), enabling the external server or cloud to calculate impedance using the digital lock-in amplifier principle.

FIG. 1c is a diagram schematically illustrating a Battery pack (1c-300) according to one embodiment of the present disclosure. FIG. 1c illustrates a Battery pack (1c-300) having a plurality of battery modules and a plurality of channels as a battery management system, which may include a plurality of Battery modules (1c-310), a BMU (Battery Management Unit) (1c-330), and a CMU (Cell Monitoring Unit) (1c-320).

This FIG. 1c may correspond to a part of the configuration of FIG. 1a. For example, the Battery module (1c-310) can be composed of a plurality of batteries (1a-130), and such a Battery module (1c-310) will be described in detail with reference to FIG. 1m. A plurality of CMUs (1c-320) and a plurality of BMUs (1c-330) can be combined to perform at least one operation of the Battery management device (1a-110).

The CMU (1c-320) can monitor and manage battery cells. The CMU (1c-320) can measure each battery cell's voltage, temperature, and impedance and deliver the data to the BMU (1c-330). The CMU (1c-320) manages Battery modules. For example, a single CMU (1c-320) can manage 2 to 8 Battery modules (1c-310).

The BMU (1c-330) can monitor and manage the state of the entire battery system. The BMU (1c-330) can receive data from each of the plurality of CMUs (1c-320) and estimate the State of Charge (SOC) and the State of Health (SOH) of the entire Battery pack based thereon. In addition, the BMU (1c-330) can protect the battery in situations such as overcharge, over-discharge, or overheating. Specifically, the BMU (1c-330) can determine frequency bands for each multi-module and multi-channel or measure set impedance values in those frequency bands to perform internal temperature estimation of the battery.

FIG. 1d is a diagram schematically illustrating a Battery module (1c-310) according to one embodiment of the present disclosure. Referring to FIG. 1d, one Battery module (1c-310) may include a plurality of Battery cells (1d-401). Specifically, the Battery module (1c-310) may have connections of a plurality of Battery cells connected in series (xS) and in parallel (xP). For example, if Battery cells connected in parallel (1d-410) are connected in parallel and Battery cells connected in series (1d-420) are connected in series, the resulting Battery module (1c-310) can be indicated as an xPxS battery module, and the series-connected unit of such Battery cells (1d-401) may be called a channel (1d-430). For example, in a 2P6S Battery module (1c-310), there can be a total of 6 channels. When there are multiple Battery modules (1c-310) in this way, it may be called a multi-module, multi-channel battery system.

According to one embodiment of the present disclosure, the Battery management device can determine an equivalent circuit model by internal temperature ranges or SOC ranges for at least one of the Battery module (1c-310), the channel (1d-430), and the Battery cell (1d-401).

FIG. 1e is a flowchart illustrating an operation of battery state estimation by the Battery management device according to one embodiment of the present disclosure. Referring to FIG. 1e, in step 1e-S510, the Battery management device can measure impedance data by frequency band of the battery. The Battery management device can set the frequency range to be measured. The Battery management device can use various frequencies in the range of mHz to kHz and select an appropriate range according to battery characteristics. Within the set frequency range, the Battery management device can sequentially apply small amplitude AC current or voltage signals at various frequencies to the battery. At each frequency, the Battery management device measures the battery's voltage and current responses to the applied signal and can also measure the phase difference. Based on the measured voltage and current data, the Battery management device can calculate the impedance at each frequency. The Battery management device can store the calculated impedance data by frequency.

According to one embodiment, in step 1e-S520, the Battery management device can create a graph representing the impedance characteristics in each internal temperature range of the battery based on the impedance data. The Battery management device can classify the impedance data into multiple internal temperature ranges, for example, −10° C., 0° C., 10° C., 20° C., 30° C., 40° C., 50° C., 60° C., and so forth. For each temperature range, the Battery management device can create a Nyquist plot. In this plot, the Battery management device places the real part of the impedance on the x-axis and the negative imaginary part on the y-axis. The Battery management device can mark each frequency point on the Nyquist plot as a dot. Typically, it may start from the right and move to the left, displaying from low frequency to high frequency. The Battery management device can connect these points to form a continuous curve. This curve represents the impedance characteristics of the battery at that temperature.

The Battery management device can create separate Nyquist plots for each temperature range. Through this, the Battery management device can visually represent the changes in impedance characteristics according to temperature. The Battery management device can store these created graphs and use them for subsequent analysis or comparison.

According to one embodiment, in step 1e-S530, the Battery management device can select a first equivalent circuit model from a plurality of set equivalent circuit models for each internal temperature range of the battery based on the graph representing impedance characteristics.

The Battery management device can consider pre-set equivalent circuit models (ECMs). For example, the following pre-set equivalent circuit models may exist:

### Rand Model:

Circuit configuration: R0 (series resistance)-(R1,C1 in parallel)-W0 (Warburg element)
Parameters: ‘R0’, ‘R1’, ‘C1’, ‘W’, ‘Wtau’
Feature: A basic battery model representing ohmic resistance, charge transfer resistance, double-layer capacitance, and diffusion effects.

### Rand_CPE Model:

Circuit configuration: R0-(R1,CPE1 in parallel)-W0
Parameters: ‘R0’, ‘R1’, ‘CPE1_q’, ‘CPE1_alpha’, ‘W’, ‘Wtau’
Feature: A variation of the Rand model that uses a constant phase element (CPE) instead of a capacitor to model non-ideal capacitive behavior.

### Two_Ladder_Wo Model:

Circuit configuration: R0-(R1,C1 in parallel)-(R2,C2 in parallel)-W0
Parameters: ‘R0’, ‘R1’, ‘C1’, ‘R2’, ‘C2’, ‘W’, ‘Wtau’
Feature: Uses two RC parallel circuits to model processes with different time constants.

### L_One_Ladder_Wo Model:

Circuit configuration: L0-R0-(R1,C1 in parallel)-W0
Parameters: ‘L0’, ‘R0’, ‘R1’, ‘C1’, ‘W’, ‘Wtau’
Feature: Adds an inductor to model inductive effects in the high-frequency region.

### L_Two_Ladder_Wo Model:

Circuit configuration: L0-R0-(R1,C1 in parallel)-(R2,C2 in parallel)-W0
Parameters: ‘L0’, ‘R0’, ‘R1’, ‘C1’, ‘R2’, ‘C2’, ‘W’, ‘Wtau’
Feature: Combines an inductor and two RC parallel circuits to model complex electrochemical processes.
   pLR_Two_Ladder_Wo Model:
Circuit configuration: (L0,R3 in parallel)-R0-(R1,C1 in parallel)-(R2,C2 in parallel)-W0
Parameters: ‘L0’, ‘R3’, ‘R0’, ‘R1’, ‘C1’, ‘R2’, ‘C2’, ‘W’, ‘Wtau’
Feature: Adds a parallel connection of inductor and resistor for complex behavior at high frequencies.

### L_pLR_Two_Ladder_Wo Model:

Circuit configuration: L0-(L1,R3 in parallel)-R0-(R1,C1 in parallel)-(R2,C2 in parallel)-W0
Parameters: ‘L0’, ‘L1’, ‘R3’, ‘R0’, ‘R1’, ‘C1’, ‘R2’, ‘C2’, ‘W’, ‘Wtau’
Feature: Uses two inductors to model more detailed high-frequency behavior.

The Battery management device can apply all the pre-set ECMs to the Nyquist plot of each internal temperature range and perform curve fitting. In this process, the Battery management device can use optimization techniques such as the Levenberg-Marquardt algorithm to estimate the parameters of each ECM. The Battery management device can calculate various performance evaluation indicators for each ECM to evaluate its performance. These indicators may include parameter variance by temperature at each SOC, MAE, MSE, RMSE, R-squared values, and other error indicators. The Battery management device can compare the performance evaluation indicators for each internal temperature range and identify the ECM that shows the best performance. The identified optimal ECM is selected as the “first equivalent circuit model” for that temperature range. The Battery management device can select different “first equivalent circuit models” for each internal temperature range. For example, at low temperatures, the One_ladder_Wo model may be optimal, whereas at high temperatures, the Two_ladder_Wo model may be more suitable. The Battery management device can store the parameter values of the selected model along with the optimal ECM information for each temperature range, and use this information for subsequent battery state estimation.

According to one embodiment, in step 1e-S540, the Battery management device can estimate the battery state based on the first equivalent circuit model. The Battery management device can estimate the battery state in various ways based on the first equivalent circuit model selected in step 1e-S540.

The Battery management device can use the parameters of the selected first equivalent circuit model to calculate the internal resistance of the battery. Since the internal resistance value directly affects the battery's power performance and heat generation, the device can evaluate the battery's power performance through it.

In addition, the Battery management device can analyze the capacitance element of the equivalent circuit model to estimate the capacity fade of the battery. By tracking changes in this value over time, the device can judge the degree of battery aging.

The Battery management device can estimate the battery's State of Health (SOH) using the first equivalent circuit model. This can be done by comparing the initial state with the current state's model parameters, allowing the device to identify the current point in the battery's overall life cycle.

The Battery management device can also use the first equivalent circuit model to estimate the battery's SOC. By comparing the impedance characteristics of the model with the actually measured impedance, the device can accurately estimate the current SOC.

Furthermore, the Battery management device can analyze the temperature dependence of the battery based on the first equivalent circuit model. Through changes in model parameters at various temperatures, the device can evaluate the effect of temperature on battery performance.

Finally, the Battery management device can monitor the battery's safety using the first equivalent circuit model. Rapid changes in model parameters or abnormal values may indicate potential safety issues, and the device can detect these and take appropriate measures.

In another embodiment, the Battery management device can determine equivalent circuit models not only by temperature ranges but also by SOC ranges based on impedance data, and estimate the battery state.

In another embodiment, the Battery management device can create graphs representing impedance characteristics by SOC range in step 1e-S520 based on impedance data. The Battery management device can first divide the battery's SOC into multiple sections, for example 0%, 10%, 20%, 30%, 40%, 50%, 60%, 70%, 80%, 90%, and 100%. For each SOC section, the Battery management device can use the previously measured impedance data by frequency band to generate terminal voltage values.

The Battery management device can overlap terminal voltage values for each SOC section to create a graph that shows the change in impedance characteristics with SOC at a glance. The Battery management device can visualize the pattern of changes in the real and imaginary parts of the impedance as SOC changes through this graph.

In another embodiment, in step 1e-S530, the Battery management device can select a first equivalent circuit model from a plurality of set equivalent circuit models for each SOC range of the battery based on the graph representing impedance characteristics, i.e., the terminal voltage values according to SOC. The Battery management device can analyze the terminal voltage values according to SOC created for each SOC section.

The Battery management device can prepare multiple pre-set ECMs, including at least one of Rand, Rand_CPE, Two_ladder_Wo, L_one_ladder_Wo, L_two_ladder_Wo, pLR_two_ladder_Wo, L_pLR_two_ladder_Wo. For each SOC section, the Battery management device can apply all the prepared ECMs and perform curve fitting. In this process, optimization techniques such as the Levenberg-Marquardt algorithm can be used. The Battery management device can calculate several indicators to evaluate each ECM's performance. These indicators may include error indicators such as parameter variance by temperature at each SOC, MAE, MSE, RMSE, R-squared values, and so forth. Based on the calculated performance indicators, the Battery management device can select the ECM with the best performance as the “first equivalent circuit model” for each SOC section. The Battery management device can store the parameter values of the selected ECM and use them for future battery state estimation.

In addition, the Battery management device can consider the battery's usage time and number of charge/discharge cycles, and periodically repeat this process to update the equivalent circuit model by SOC section.

FIG. 1f is a flowchart illustrating the operation of selecting an equivalent circuit model by the Battery management device according to one embodiment of the present disclosure. The operation of the Battery management device in FIG. 1f may correspond to step 1e-S530 in FIG. 1e. Referring to FIG. 1f, in step 1f-S610, the Battery management device can select a first equivalent circuit model from among a plurality of set equivalent circuit models for each internal temperature range or SOC range of the battery based on the graph representing the impedance characteristics.

The Battery management device can set the internal temperature ranges and SOC ranges of the battery. For example, internal temperature ranges can be set from −10° C. to 60° C. at 10° C. intervals, and SOC ranges can be set from 0% to 100% at 10% intervals. The Battery management device can select a plurality of predefined equivalent circuit models as candidates. Such models may include Rand, Rand_CPE, Two_ladder_Wo, L_one_ladder_Wo, etc.

The Battery management device can select as the first equivalent circuit model the one that most closely resembles the impedance characteristic graph for each temperature or SOC range. In this process, the device can consider the shape of the graph, the slope of the curve, and characteristic points.

The Battery management device can evaluate the initial suitability by comparing the theoretical impedance response of the selected first equivalent circuit model with the actually measured impedance data. This evaluation can be based on the match of frequency response and characteristic curves. The Battery management device can comprehensively consider changes in impedance characteristics at various temperatures and SOC conditions to select a model. Through this, the device can identify a model that shows stable performance over a wide operating range. The Battery management device can consider the computational complexity of each equivalent circuit model. The device can select a model balancing performance and efficiency, taking into account its own processing capability and required real-time performance.

According to one embodiment, in step 1f-S620, the Battery management device can estimate parameters of the first equivalent circuit model. The Battery management device can identify the parameters to be estimated according to the structure of the selected equivalent circuit model. These generally include elements such as resistors (R), capacitors (C), inductors (L), and Warburg impedance (W).

The Battery management device can use a curve fitting method to estimate parameters. In particular, the Levenberg-Marquardt algorithm can be used to estimate parameters. In this process, the Battery management device sets initial values of the parameters. The initial values can be set based on previous experience or general battery characteristics.

According to one embodiment, in step 1f-S630, the Battery management device can generate error indicators. The Battery management device can calculate the variance of parameter values according to temperature changes for each SOC range as follows. The Battery management device collects parameter values (e.g., R0, R1, C1, etc.) at all temperature ranges (−10° C., 0° C., 10° C., . . . , 60° C.) for each SOC range (e.g., 0%, 10%, 20%, . . . , 90%, 100%), and calculates the variance in parameter values according to temperature for each parameter. The Battery management device can then take the mean of the variance values of all parameters to obtain the average parameter variance at that SOC. Based on the calculated variance values, the Battery management device can evaluate the stability of the parameters as follows.

The Battery management device can compare the measured impedance data with the impedance data predicted by the selected equivalent circuit model to calculate at least one of MAE, MSE, RMSE, and R-squared values. Alternatively, the Battery management device can calculate parameter variance by temperature for each SOC. For example, the Battery management device can normalize the average parameter variance at each SOC range. Based on the normalized value, the Battery management device can calculate a parameter stability score, for example, Stability score=1/(normalized average parameter variance).

The Battery management device can evaluate the complexity of the selected equivalent circuit model as follows. The Battery management device counts the number of parameters of the model. Depending on the number of parameters, the device assigns a complexity score. For example, Complexity score=1/(number of parameters).

The Battery management device can integrate all the indicators calculated above to create a final performance index as follows. For example, the device can assign weights to each indicator to calculate a composite score: Composite score=w1*(1/RMSE)+w2*R-squared+w3*Stability score+w4*Complexity score, where w1, w2, w3, w4 are weights for each indicator's importance.

According to one embodiment, in step 1f-S640, the Battery management device can compare the error indicators to a predetermined threshold. According to one embodiment, if the error indicators exceed the predetermined threshold, the Battery management device can proceed to step 1f-S610 to select a second equivalent circuit model different from the first equivalent circuit model. If the error indicators are below the predetermined threshold, the Battery management device can proceed to step 1f-S650 to adjust parameters.

Alternatively, if the composite score or a final performance indicator is below a predetermined threshold, the Battery management device can proceed to step 1f-S610 to select a second equivalent circuit model different from the first equivalent circuit model. If the final performance indicator exceeds the predetermined threshold, the device can proceed to step 1f-S650 to adjust parameters.

The Battery management device can set thresholds for each performance indicator or for the entire error indicator. For example, the RMSE threshold could be 0.05, the R-squared threshold 0.95, and the parameter variance threshold 0.1. The Battery management device can compare each performance indicator with its corresponding threshold. In this process, if the RMSE is greater than the threshold, the device determines that the model's accuracy is low. If the R-squared is less than the threshold, the device determines that the model's explanatory power is insufficient. If the parameter variance is greater than the threshold, the device determines that the model's stability is low.

If the performance is deemed insufficient, the Battery management device can return to step 1f-S610 to select another equivalent circuit model, i.e., the second equivalent circuit model.

According to one embodiment, in step 1f-S650, the Battery management device can re-evaluate the performance of the adjusted parameters to determine the equivalent circuit model. According to one embodiment, if the error indicators in step 1f-S640 are below the threshold, the Battery management device can finely adjust the parameters of the equivalent circuit model. In this process, the Battery management device can use the Levenberg-Marquardt algorithm or other optimization algorithms to adjust parameter values. The Battery management device can re-evaluate the model's performance using the fine-tuned parameters. In this process, the Battery management device can recalculate RMSE, R-squared values, and parameter variance by temperature at each SOC. Based on the re-evaluation results, the Battery management device can finally determine the equivalent circuit model and its parameters. This decision can be made by comprehensively considering the overall performance indicators and parameter stability.

FIG. 1g is a diagram comparing a first equivalent circuit model having first parameters with the impedance characteristics at −10° C. according to one embodiment of the present disclosure, and FIG. 1h is a diagram comparing a second equivalent circuit model having second parameters with the impedance characteristics at −10° C. according to one embodiment of the present disclosure.

Referring to FIGS. 1g and 1h, these figures show a Nyquist plot representing the impedance characteristics of the battery at −10° C. and compare simulation values according to the equivalent circuit model. Specifically, FIG. 1g compares, for example, the L_one_ladder_Wo model as a first equivalent circuit model at −10° C. in an embodiment of the battery management system and the Nyquist plot representing the impedance characteristics. FIG. 1h compares, for example, the L_two_ladder_Wo model as a second equivalent circuit model at −10° C. in an embodiment of the battery management system and the Nyquist plot representing the impedance characteristics.

As described above, the battery management system can select one of the first equivalent circuit model and the second equivalent circuit model based on the error indicators and adjust the parameters with reference to the battery's Nyquist plot. In this manner, the management system can monitor the battery state under various temperature range conditions and select an equivalent circuit model.

FIG. 1i is a diagram comparing a first equivalent circuit model having first parameters with impedance characteristics according to one embodiment of the present disclosure, and FIG. 1j is a diagram comparing a first equivalent circuit model having second parameters with impedance characteristics according to one embodiment of the present disclosure.

FIG. 1i shows a graph comparing impedance characteristics with a first equivalent circuit model having first parameters, with R2(magnitude): 0.9728, R2(phase): 0.17836, R2(real): 0.95877, and R2(imag): 0.29501. FIG. 1j shows a graph comparing impedance characteristics with a first equivalent circuit model having second parameters, with R2(magnitude): 0.99948, R2(phase): 0.99877, R2(real): 0.99949, and R2(imag): 0.99843. Comparing FIGS. 1i and 1j shows that the first equivalent circuit model has higher accuracy with the second parameters than with the first parameters, so the battery management system can adjust to the second parameters.

FIG. 1k is a diagram showing the distribution of parameters by temperature according to SOC of the first equivalent circuit model determined by the Battery management device according to one embodiment of the present disclosure, and FIG. 1l is a diagram showing the distribution of parameters by temperature according to SOC of the second equivalent circuit model determined by the Battery management device according to one embodiment of the present disclosure.

FIG. 1k shows the distribution of parameters by temperature according to SOC of the first equivalent circuit model. The model parameters include R0, R1, and Wo, and it shows how each parameter changes with temperature. FIG. 1l shows the distribution of parameters by temperature according to SOC of the second equivalent circuit model. The model parameters include R0, R1, R2, and Wo, and it shows how each parameter changes with temperature.

Comparing FIGS. 1k and 1l, the distribution of parameters by temperature according to SOC in the first equivalent circuit model is more uniform, i.e., the variance of parameters by temperature according to SOC is smaller than that of the second equivalent circuit model. The Battery management device can select the first equivalent circuit model from among the plurality of set equivalent circuit models because its SOC-based parameter distribution by temperature has a smaller variance.

FIG. 1m is a diagram comparing voltage estimation values by model and terminal voltage values according to SOC in one embodiment of the present disclosure. FIG. 1m can explain the process by which the Battery management device selects an optimal model from a plurality of set equivalent circuit models for various SOC ranges. The Battery management device can compare the R2 values of voltage estimation by a first equivalent circuit model (1RC-ladder) and a second equivalent circuit model (2RC-ladder) with the terminal voltage value at SOC 50%. The Battery management device can determine the second equivalent circuit model as the equivalent circuit model at the SOC 50% section by comparing the R2 value of the first equivalent circuit model (0.89332) and the R2 value of the second equivalent circuit model (0.98547).

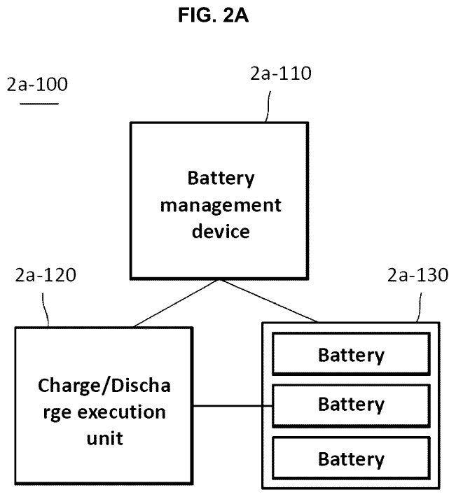

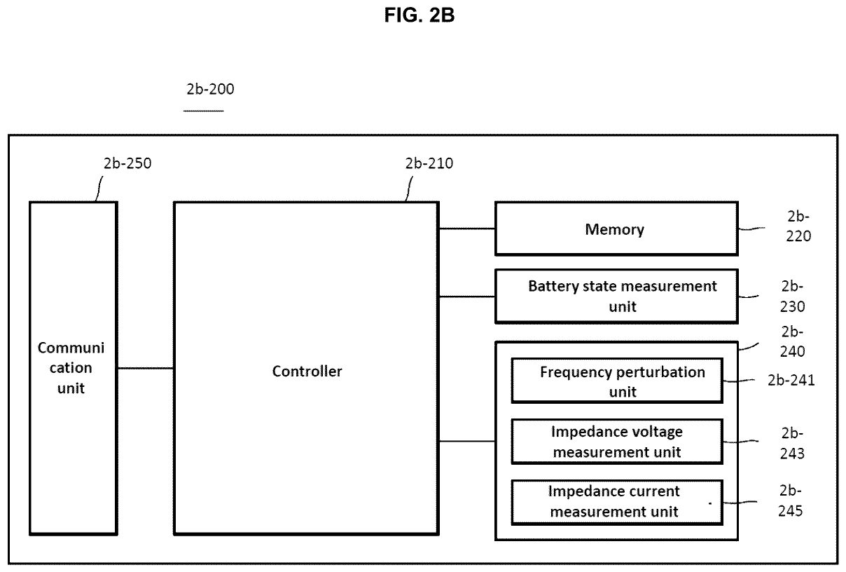

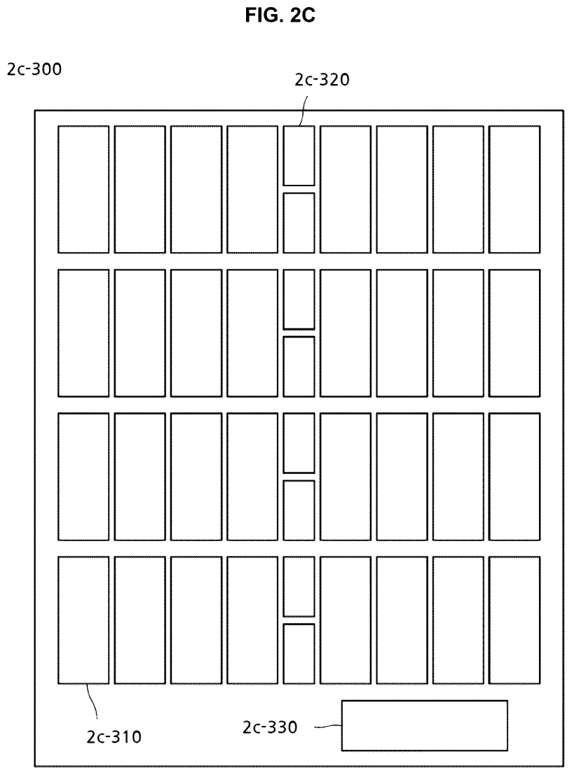

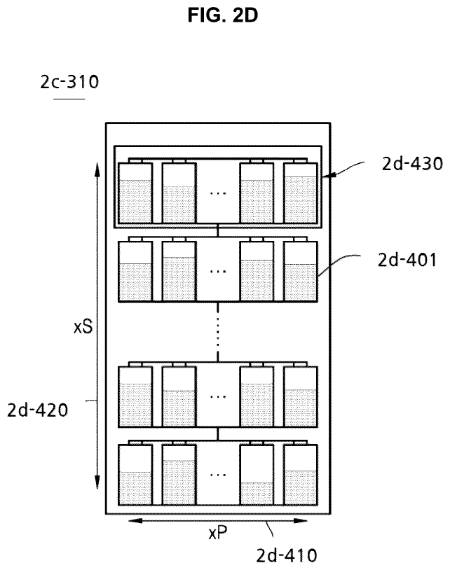

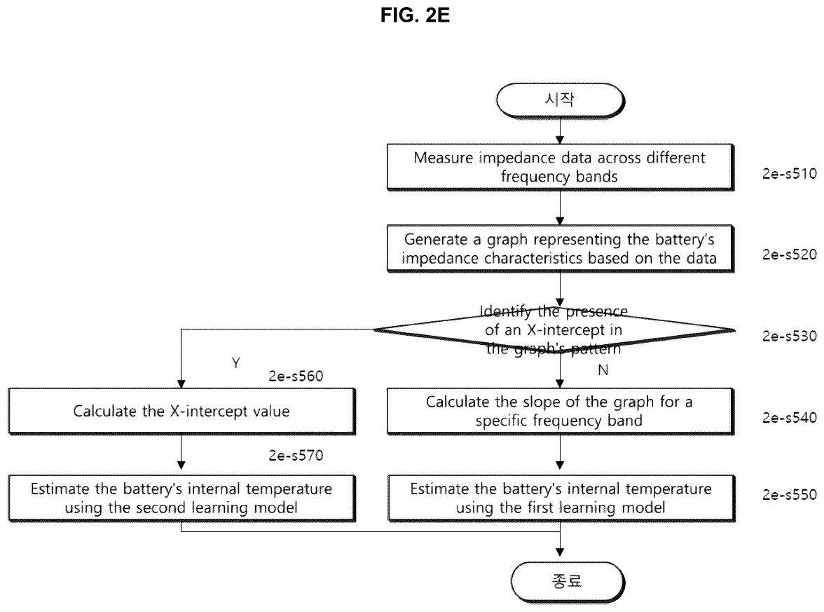

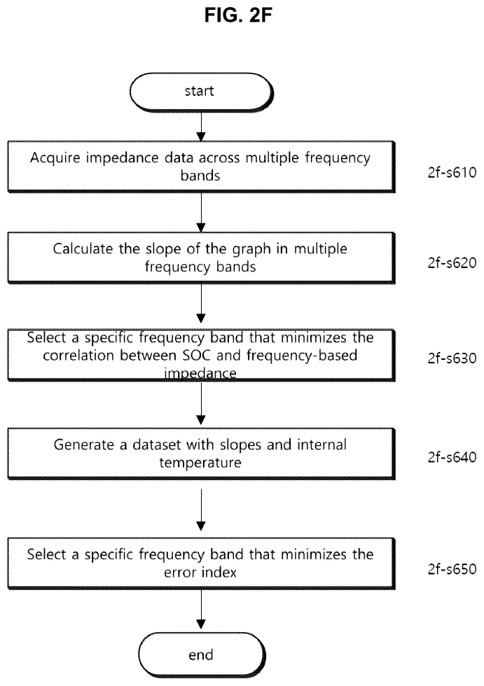

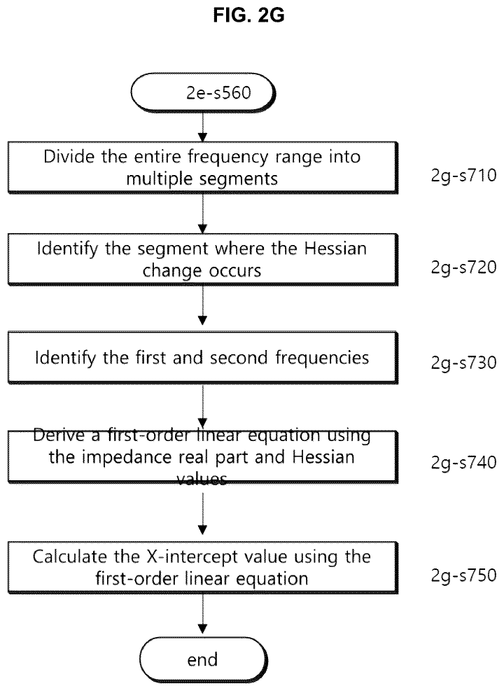

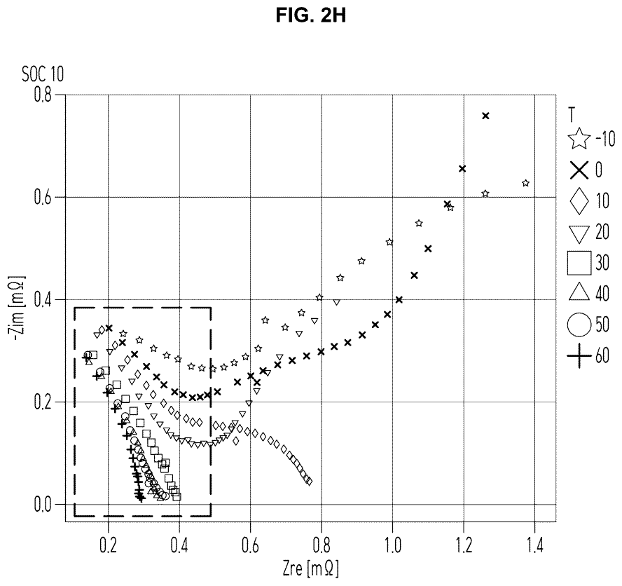

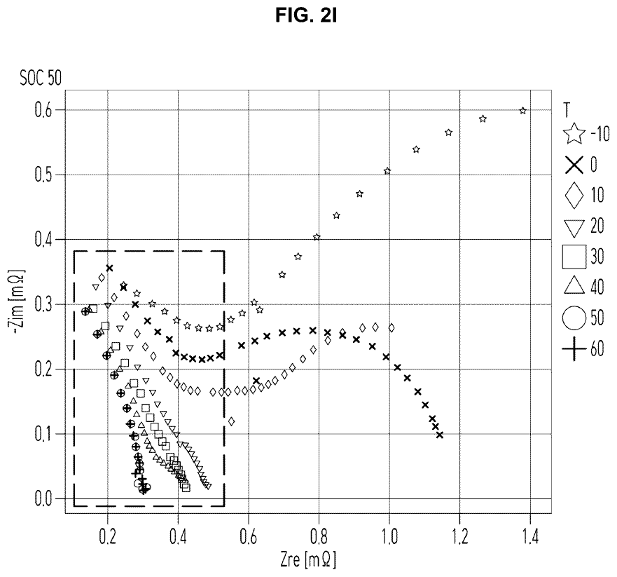

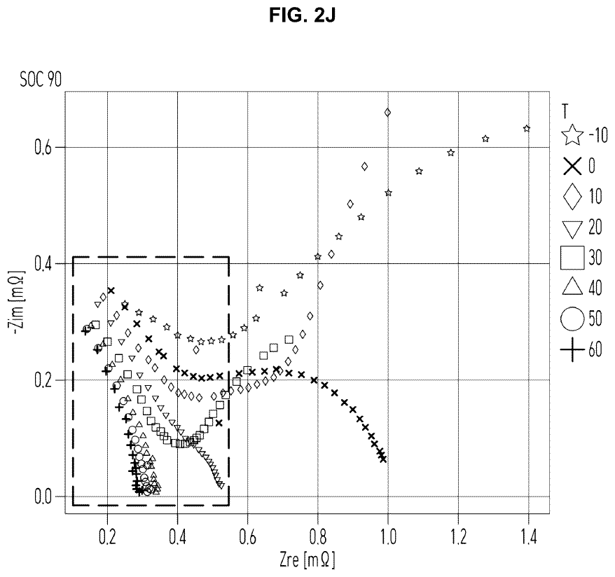

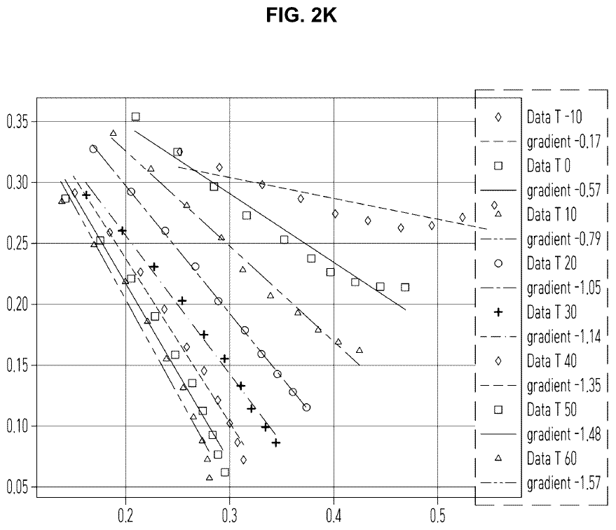

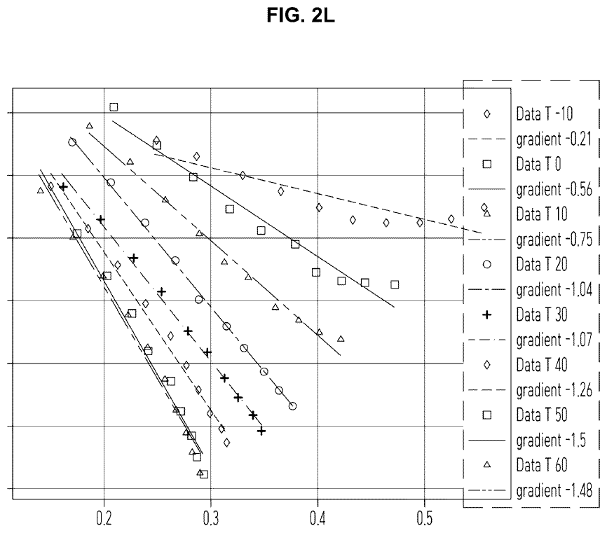

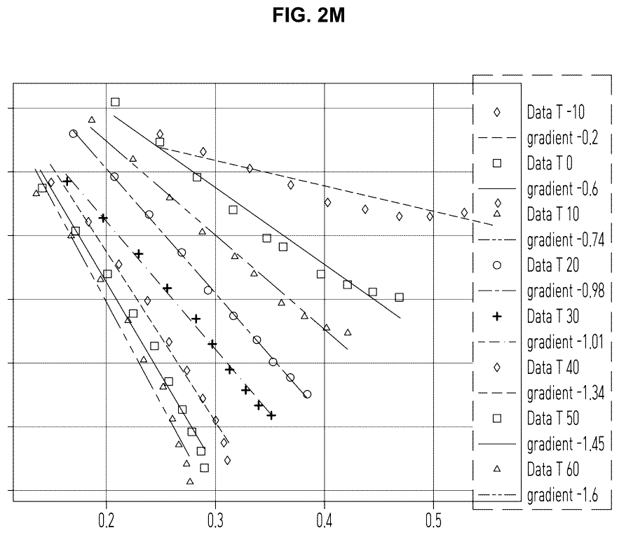

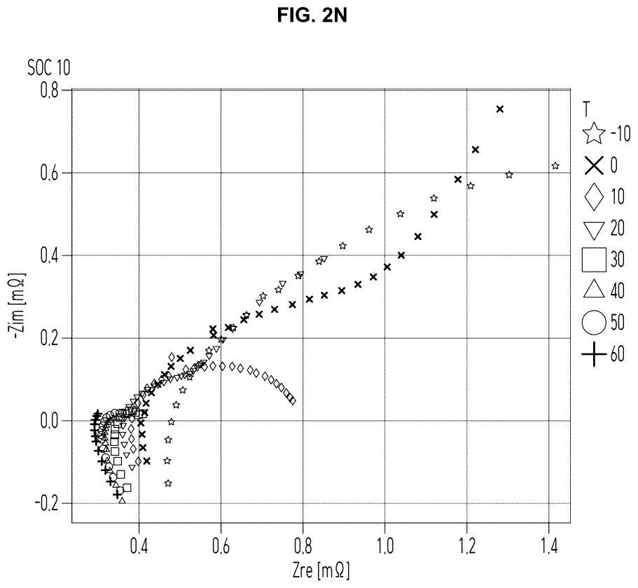

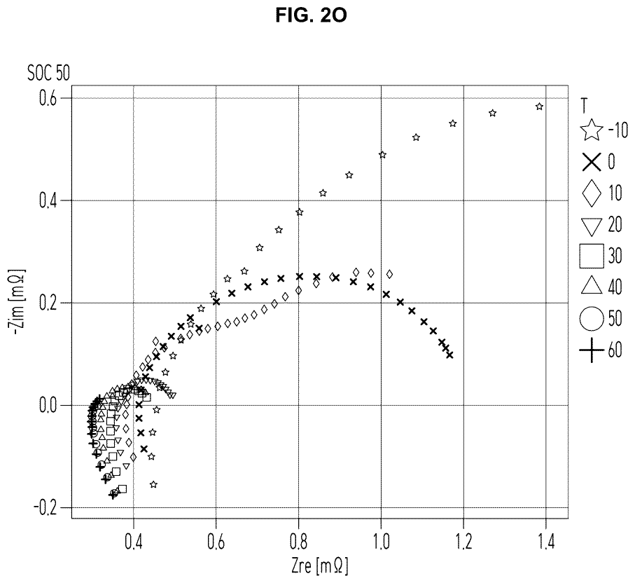

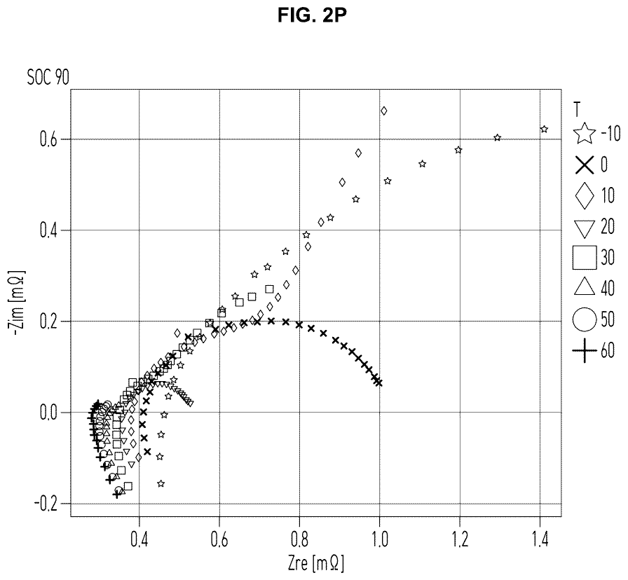

Referring to FIG. 2a, the management system (2a-100) may include a battery management system (BMS, Battery Management System) (2a-110), a charge/discharge execution unit (Charge/Discharge execution unit) (2a-120), and a plurality of batteries (2a-130).

The plurality of batteries (2a-130) may be devices subject to internal temperature and fire prediction, can be charged or discharged by being connected to the charge/discharge execution unit (2a-120), and can be managed by being connected to the battery management device (BMS) (2a-110).

The charge/discharge execution unit (2a-120) may be controlled by the battery management device (2a-110) to perform charging or discharging for the connected battery (2a-130).

The battery management device (2a-110), as a device controlling battery charging and discharging, can perform operations such as battery state of charge (SOC) measurement and battery state monitoring. Specifically, the battery management device (2a-110) may perform current measurement of the battery (2a-130) mounted in an ESS (Energy Storage System), an electric vehicle (BEV), or the like, cell voltage measurement, surface temperature measurement, SOC estimation, cell balancing, relay or FET control, fault diagnosis, fire prediction, and so forth.

According to an embodiment of the present disclosure, the battery management device (2a-110) can estimate the internal temperature of the battery (2a-130) and perform fire diagnosis and fire management. Such a battery management device (2a-110) can perform operations according to an embodiment of the present disclosure. The battery management device (2a-110) will be described in detail with reference to FIG. 2b.

According to an embodiment of the present disclosure, the management system (2a-100) may include a separate server (not shown). For example, the server may include a plurality of set equivalent circuit models, and the battery management device (2a-110) may transmit information on the impedance of the battery (2a-130) to the server and receive information on the internal temperature of the battery from the server to manage the battery (2a-130).

FIG. 2b is a schematic diagram showing a configuration (2b-200) of the battery management device (2a-110) according to an embodiment of the present disclosure.

Referring to FIG. 2b, the battery management device (2a-110) is shown as being configured by a controller (Controller) (2b-210), a memory (Memory) (2b-220), a battery state measurement unit (Battery state measurement unit) (2b-230), an impedance measurement unit (Impedance measurement unit) (2b-240), and a communication unit (Communication unit) (2b-250), but is not necessarily limited thereto. For example, the controller (2b-210), the memory (2b-220), the battery state measurement unit (2b-230), the impedance measurement unit (2b-240), and the communication unit (2b-250) may each exist as physically independent components.

The memory (2b-220) can store various data for the overall operation of the battery management device (2a-110), such as programs for processing or control by the controller (2b-210) in the battery management device (2a-110). The memory (2b-220) can store multiple application programs running therein, data for operation of the battery management device (2a-110), and instructions. The memory (2b-220) may be implemented as internal memory such as ROM and RAM included in the controller (2b-210), or as memory separate from the controller (2b-210).

According to an embodiment, the memory (2b-220) can store a plurality of set equivalent circuit models, the current of the battery (2a-130), cell voltage, surface temperature, SOC, and the like. The memory (2b-220) may be implemented as internal memory included in the controller (2b-210) or as a separate external memory.

The battery state measurement unit (2b-230) can measure the voltage of battery cells, perform cell balancing, and measure the surface temperature of the battery cells. The battery state measurement unit (2b-230) can measure the cell voltage, cell balancing, internal temperature, and surface temperature of the battery cell and provide that data to the controller (2b-210).

The impedance measurement unit (2b-240) can measure the impedance of the battery for each frequency band. The impedance measurement unit (2b-240) can be implemented as a frequency perturbation unit (Frequency perturbation unit) (2b-241), an impedance voltage measurement unit (Impedance voltage measurement unit) (2b-243), and an impedance current measurement unit (Impedance current measurement unit) (2b-245). The impedance measurement unit (2b-240) can measure the impedance of the battery using EIS (Electrical Impedance Spectroscopy). Specifically, the impedance measurement unit (2b-240) applies infinitesimal sinusoidal current and voltage signals from high frequency to low frequency, and analyzes the impedance by measuring changes in amplitude and phase in a range that does not deviate from the battery's electrical and thermal equilibrium states using the impedance voltage and impedance current signals. The impedance measurement unit (2b-240) may apply a frequency band designated by the controller (2b-210) to the battery (2a-130) to analyze the impedance and provide at least one of the impedance voltage, impedance current, and impedance to the controller (2b-210). The measurement unit may extract the necessary signals through passive and active filters for the impedance voltage and current. The filtering function of the measurement unit may be implemented by ICs, OPAMPs, and RLC components, or by an MCU and RLC components. After filtering, the signals may be provided to the ADC (Analog Digital Converter) of the controller. The impedance measurement unit (2b-240) may execute its functions by one or more processors.

The frequency perturbation unit (2b-241) can apply frequency signals to the battery to measure the impedance of the battery in each frequency band. The frequency perturbation unit (2b-241) can apply sinusoidal current and voltage signals for a frequency band specified by the controller (2b-210).

The impedance voltage measurement unit (2b-243) can measure the impedance voltage of the battery perturbed by the frequency perturbation unit (2b-241). The impedance voltage measurement unit (2b-243) can measure the voltage applied to the battery by the signals applied by the frequency perturbation unit (2b-241).

The impedance current measurement unit (2b-245) can measure the impedance current of the battery perturbed by the frequency perturbation unit (2b-241). The impedance current measurement unit (2b-245) can measure the current flowing in the battery based on the signals applied by the frequency perturbation unit (2b-241).

The communication unit (2b-250) performs functions for transmitting and receiving signals through a network.

All or part of the communication unit (2b-250) can be referred to as a transmitter, a receiver, or a transceiver. The communication unit (2b-250) can provide a function for at least one other node to communicate with the battery management device (2a-110) via a communication network. According to one embodiment of the present disclosure, when a request signal is generated according to program code stored in a recording device such as the memory (2b-220) of the battery management device (2a-110), the request signal can be transmitted to at least one other node through the communication network under the control of the communication unit (2b-250). Conversely, a control signal, command, content, file, etc., provided under the control of at least one other node's processor can be received by the battery management device (2a-110) through the communication unit (2b-250). According to one embodiment, the communication unit (2b-250) can transmit impedance information to the server and receive internal temperature information of the battery from the server. Also, according to one embodiment, the communication unit (2b-250) can transmit and receive a plurality of set equivalent circuit models from the server. The battery management device (2a-110) can acquire various set equivalent circuit models through the communication unit (2b-250).

The controller (2b-210) may be a configuration for controlling the battery management device (2a-110) overall.

The controller (2b-210) can analyze the type of the generated graph and identify whether there is an X-intercept. If the graph is determined to be a type without an X-intercept, the controller (2b-210) can perform operations to calculate the slope of the graph in a specific frequency band. In the slope calculation process, the controller (2b-210) minimizes the error index of a first learning model, and the slope calculation unit can select a specific frequency band that minimizes the correlation between the SOC (State of Charge) and the slope. Through this, the controller (2b-210) can calculate a slope value.

Using the calculated slope value, the controller (2b-210) can perform an operation to estimate the internal temperature. In this process, the first learning model, which has learned the correlation between the slope and the internal temperature, can be used. The first learning model may be a model learned in advance using a training dataset that includes a graph slope and an internal temperature in a specific frequency band.

In estimating the internal temperature, the controller (2b-210) can use a polynomial regression model. The order of this model can be determined through performance evaluation, balancing accuracy and computational load.

A Nyquist plot can be used as the graph representing impedance characteristics. The controller (2b-210) can analyze this graph to diagnose the state of the battery.

If it is determined that the graph is a type with an X-intercept, the controller (2b-210) can apply a different method of estimating the internal temperature. In this case, the controller (2b-210) calculates the X-intercept value, and uses a second learning model that has learned the correlation between this value and the internal temperature to estimate the internal temperature.

In the process of calculating the X-intercept value, the controller (2b-210) can identify two frequencies at which the sign of the imaginary part of the impedance changes, and obtain a first linear equation using the real and imaginary parts of the impedance corresponding to these frequencies. Through this linear equation, the X-intercept value can be calculated.

In the frequency identification process, the controller (2b-210) can divide the entire frequency range into multiple sections, measure the impedance at the representative frequency of each section, and identify the section in which the imaginary part sign changes. Subsequently, measurements can be made within that section to identify the frequency.

Specifically, the controller (2b-210) can control the operation of the battery management device (2a-110) using various programs stored in the memory (2b-220) of the battery management device (2a-110). The controller (2b-210) may include a CPU, RAM, ROM, a system bus, and the like. The controller (2b-210) can be implemented as a single CPU or multiple CPUs (or DSP, SOC). For example, the controller (2b-210) can be implemented as a digital signal processor (DSP), a microprocessor, or a TCON (Time controller). However, it is not limited thereto, and it can be defined by or include one or more of a central processing unit (CPU), MCU (Micro Controller Unit), MPU (micro processing unit), controller, application processor (AP), communication processor (CP), or an ARM processor. Further, the controller (2b-210) may be implemented as an SOC (System on Chip) or LSI (large scale integration) with embedded processing algorithms, or may be implemented in an FPGA (Field Programmable Gate Array) form.

According to one embodiment, the controller (2b-210) can control the impedance measurement unit (2b-240) to apply signals in a frequency band to the battery. The controller (2b-210) may receive impedance voltage and impedance current from the impedance measurement unit (2b-240) and calculate impedance using the digital lock-in amplifier principle. The controller (2b-210) may also receive impedance directly from the impedance measurement unit (2b-240). Such impedance may be represented by real and imaginary parts, and the controller (2b-210) can calculate the magnitude and phase of the impedance. In addition, the controller (2b-210) can transmit and receive impedance voltage and impedance current values to and from an external server or cloud via the communication unit (2b-250), so that the external server or cloud can calculate the impedance using the digital lock-in amplifier principle.

According to one embodiment, the controller (2b-210) can acquire impedance data of the battery for each frequency band from the impedance measurement unit (2b-240). The controller (2b-210) and the impedance measurement unit (2b-240) are directly connected by a data bus so that measured impedance data can be received in real time. The impedance data is distinguished by frequency, and includes the magnitude and phase of the impedance at each frequency or includes real and imaginary parts of the impedance. The controller (2b-210) can temporarily store the received data in internal memory or store it long-term in the memory (2b-220).

FIG. 2c is a schematic diagram of a battery pack (2c-300) according to an embodiment of the present disclosure.

FIG. 2c is a schematic diagram of a battery pack (2c-300) according to an embodiment of the present disclosure. FIG. 2c shows a battery management system for a battery pack (2c-300) having a plurality of battery modules and a plurality of channels, and may include a plurality of battery modules (2c-310), a battery management unit (BMU, Battery Management Unit) (2c-330), and a cell monitoring unit (CMU, Cell Monitoring Unit) (2c-320).

Such FIG. 2c may correspond to a part of the configuration of FIG. 2a. For example, the battery module (2c-310) can be configured by a plurality of batteries (2a-130), and the battery module (2c-310) will be described in detail below. A plurality of CMUs (2c-320) and a plurality of BMUs (2c-330) may combine to perform at least one operation of the battery management device (2a-110).

The CMU (2c-320) can monitor and manage the battery cells. It can measure the voltage, temperature, and impedance of each battery cell and deliver data to the BMU (2c-330). The CMU (2c-320) manages the battery module, and for example, one CMU (2c-320) can manage two to eight battery modules (2c-310).

The BMU (2c-330) can monitor and manage the state of the entire battery system. It can receive data from each of the plurality of CMUs (2c-320) and estimate the state of charge (SOC) and state of health (SOH) of the entire battery pack. In addition, the BMU (2c-330) can protect the battery in situations such as overcharging, overdischarging, and overheating. Specifically, the BMU (2c-330) can determine a frequency band for each multi-module and multi-channel, or measure set impedance values in the frequency band to estimate the internal temperature of the battery.

FIG. 2d is a schematic diagram of a battery module according to an embodiment of the present disclosure. Referring to FIG. 2d, one battery module (2c-310) can include a plurality of battery cells (2d-401). Specifically, the battery module (2c-310) can have a parallel and series connection of a plurality of battery cells (2d-401). For example, a battery module (2c-310) having battery cells xP (2d-410) connected in parallel and battery cells xS (2d-420) connected in series can be referred to as an xPxS battery module, and the series connection unit of such battery cells (2d-401) can be referred to as a channel (2d-430). For example, in a 2P6S battery module (2c-310), a total of 6 channels may be present. When a plurality of such battery modules (2c-310) are present, it can be referred to as a multi-module, multi-channel battery system.

According to an embodiment of the present disclosure, the battery management device can estimate the battery state or the internal temperature of the battery for at least one of the battery module (2c-310), the channel (2d-430), and the battery cell (2d-401).

FIG. 2e is a flowchart illustrating an internal temperature estimation operation of the battery management device according to an embodiment of the present disclosure.

Referring to FIG. 2e, in step 2e-S510, the battery management device can measure impedance data for each frequency band. The battery management device can set the frequency range to be measured. The battery management device can use various frequencies in a range from mHz to kHz and select an appropriate range according to battery characteristics. The battery management device can apply a small amplitude AC current or voltage signal at various frequencies sequentially within the set frequency range. At each frequency, the battery management device measures the voltage and current response of the battery to the applied signal and can also measure the phase difference. Based on the measured voltage and current data, the battery management device can calculate the impedance at each frequency. The battery management device can store the calculated impedance data by frequency.

According to one embodiment of the battery management device, in step 2e-S520, it can generate a graph representing the impedance characteristics of the battery based on the impedance data.

The battery management device can arrange and classify the obtained impedance data by frequency band. It can separate the real and imaginary parts of the impedance corresponding to each frequency. Next, the battery management device selects a suitable graph type to visualize the impedance data. For example, a Nyquist plot can be used to represent the impedance characteristics of the battery. The Nyquist plot places the real part of the impedance on the x-axis and the negative of the imaginary part of the impedance on the y-axis. The battery management device can place data points corresponding to each frequency on the Nyquist plot. By connecting data points from high frequency to low frequency, a continuous curve is formed.

In generating the graph, the battery management device can perform scaling and normalization of the data. This is to effectively represent impedance values of different magnitudes on the same graph. For example, if the ranges of the real and imaginary parts of the impedance differ greatly, appropriate scaling can improve the readability of the graph.

Additionally, the battery management device can mark key feature points on the graph. In the Nyquist plot, feature points such as the X-intercept or the peak of a semicircle are important indicators. These feature points can serve as indicators representing the resistive or capacitive elements of the battery.

According to one embodiment, in step 2e-S530, the battery management device can identify the presence or absence of an X-intercept in the graph. If no X-intercept is identified, the process proceeds to step 2e-S540, and if an X-intercept is identified, the process proceeds to step 2e-S560.

First, the battery management device analyzes the impedance characteristic graph represented as a Nyquist plot. In this graph, the x-axis corresponds to the real part of the impedance and the y-axis corresponds to the negative imaginary part of the impedance. The battery management device checks whether there is a point where the graph crosses the x-axis. If an X-intercept exists, the battery management device recognizes it as a typical Nyquist plot shape. This shape is often observed at normal or low temperatures and may represent a normal frequency response characteristic of the battery. The battery management device can recognize that the X-intercept value represents the electrolyte resistance of the battery and reflects aging characteristics.

On the other hand, if there is no X-intercept, the battery management device recognizes it as an atypical Nyquist plot shape. Such a shape may be observed mainly under high temperature conditions or certain battery states.

To determine the presence of an X-intercept, the battery management device can sequentially analyze the data points of the graph from low frequency to high frequency. It checks if a crossing point with the x-axis occurs. In this process, the battery management device may set a certain threshold to avoid incorrect judgments due to measurement errors or noise. Also, the battery management device can consider the overall shape of the graph. If the graph has an X-intercept, it generally shows a semicircle or a distorted semicircle. If the graph has no X-intercept, it may show a shape close to a straight line or an irregular curve. The battery management device can use such an overall shape to determine the presence of an X-intercept.

According to the results of identifying the presence of the X-intercept, the battery management device selects the internal temperature estimation method. If there is no X-intercept, the battery management device proceeds to step 2e-S540 and applies a method using the slope of the graph. If there is an X-intercept, the battery management device proceeds to step 2e-S560 and applies a method using the X-intercept value.

According to one embodiment of the present disclosure, in step 2e-S540, if the graph is a type without an X-intercept, the battery management device can calculate the slope of the graph in a specific frequency band.

First, the battery management device can divide the entire frequency range into multiple sections. For example, the range from 0.01 Hz to 1 MHz can be divided by decade. Within each decade, the battery management device can select a certain number of frequency points to measure.

Next, the battery management device performs impedance measurements at the selected frequency points. Through this process, it obtains the real and imaginary parts of the impedance corresponding to each frequency point.

Based on the measured data, the battery management device can generate a Nyquist plot. In this plot, the x-axis represents the real part of the impedance and the y-axis represents the negative imaginary part of the impedance.

The battery management device selects a specific frequency band on the Nyquist plot to calculate the slope. This specific frequency band is chosen to minimize the influence of the SOC (State of Charge) and to have a high correlation with internal temperature. For example, a frequency band between about 1 kHz and 50.25 Hz may be selected.

In the selected frequency band, the battery management device can use polynomial regression or curve fitting methods to calculate the slope. At this time, a first-order or second-order polynomial can be used, and the selection of the order can be determined through performance indicators such as RMSE (Root Mean Square Error). The battery management device stores the calculated slope value and prepares it for use in internal temperature estimation. In this process, additional information such as SOC and ambient temperature can be recorded together. The battery management device can verify the reliability of the calculated slope by repeating the measurement multiple times and using the average value to minimize the effects of measurement errors or transient noise.

According to one embodiment, in step 2e-S550, the battery management device can estimate the internal temperature of the battery using a first learning model that has learned the correlation between the slope and the internal temperature.

The battery management device can load the first learning model prepared in advance. This learning model can be a model pre-trained using a training dataset including a graph slope and internal temperature in a specific frequency band. The training dataset may be composed of data measured under various temperature conditions and SOC levels.

The battery management device can use the slope value calculated in step 2e-S540 as input. The battery management device inputs the slope value into the loaded first learning model to predict the internal temperature. In this process, a polynomial regression model can be used, and the order of the model can be determined through prior performance evaluation. For example, a first-order or second-order polynomial regression model can be used, and depending on each case, an optimal frequency band may be selected.

The battery management device can evaluate the reliability of the predicted internal temperature value. For this, uncertainty of the prediction can be calculated, or the model's confidence interval can be used. If the reliability is low, the battery management device can perform additional measurements or verification through other methods.

At step 2e-S560, if the impedance characteristic graph is a type with an X-intercept, the battery management device can calculate the X-intercept value.

The battery management device can identify two frequencies at which the sign of the imaginary part of the impedance changes. To do this, the entire frequency range is divided into multiple sections, and the impedance at the representative frequency of each section is measured. By confirming the sign of the imaginary part of the measured impedance, the battery management device identifies the section where the sign changes.

Once the section is identified, the battery management device performs more precise measurements within that section to determine the exact frequencies. Through this process, the battery management device precisely determines the first frequency (f1) and the second frequency (f2).

Next, the battery management device uses the real and imaginary parts of the impedance corresponding to the identified two frequencies to obtain a first linear equation. This linear equation can have the following form: y=ax+b Here, x represents the real part of the impedance, y represents the imaginary part of the impedance, and a and b are coefficients that can be calculated using the two frequency points.

Using this linear equation, the battery management device calculates the X-intercept value. Since the X-intercept is the x-value when y=0, the battery management device substitutes y=0 into the above equation to find x.

According to one embodiment, in step 2e-S570, the battery management device can estimate the internal temperature using a second learning model that has learned the correlation between the X-intercept value and the internal temperature.

The battery management device can load a second learning model prepared in advance. This model may have been trained using data of the X-intercept values measured under various conditions and the corresponding actual internal temperature data. The learning model can be a linear regression, polynomial regression, or a machine learning algorithm.

The battery management device can apply the currently obtained X-intercept value from step 2e-S560 as input to the second learning model. In this process, the model processes the input X-intercept value and outputs the corresponding internal temperature.

The battery management device can perform additional calibration based on the predicted temperature value. This calibration may consider the current state of the battery, the usage environment, or additional information obtained from other sensors. For example, the battery management device can adjust the estimated temperature by reflecting factors such as SOC or external temperature.

The battery management device can evaluate the reliability of the estimated internal temperature. For this, it can analyze the uncertainty of the model or check consistency with past data.

FIG. 2f is a flowchart illustrating an operation of selecting a specific frequency band by the battery management device according to an embodiment of the present disclosure.

Referring to FIG. 2f, at step 2f-S610, the battery management device can acquire impedance data from multiple frequency bands. The battery management device can measure impedance data by frequency band. It can set the frequency range to be measured. The battery management device can use various frequencies from mHz to kHz and selects an appropriate range according to battery characteristics. The battery management device applies small amplitude AC signals at various frequencies sequentially within the set frequency range and measures the voltage and current responses as well as the phase differences. The battery management device calculates the impedance at each frequency and stores the impedance data by frequency.

According to an embodiment, in step 2f-S620, the battery management device can calculate the graph slope in multiple frequency bands. The battery management device can convert the impedance data for each frequency band into a Nyquist plot. In the Nyquist plot, the x-axis is the real part of the impedance and the y-axis is the negative imaginary part. The battery management device can select data points in each frequency band considering the characteristics of the frequency band and data distribution. For example, it can select 10 data points between 1 kHz and 125 Hz, and use linear regression or polynomial regression to calculate the slope in each frequency band.

According to one embodiment, in step 2f-S630, the battery management device can select a specific frequency band that minimizes the correlation between SOC and the slope. The battery management device first obtains impedance data in the entire frequency range at various SOC levels (e.g., 10%, 20%, . . . , 90%, 100%). Based on the collected data, the battery management device identifies a specific frequency band where, under a constant internal temperature, the slope change with respect to SOC is minimized. That is, through graph analysis, when maintaining a constant internal temperature, the battery management device identifies a frequency band in which the slope variation due to SOC changes is low. In this frequency band, the slope value remains stable regardless of SOC, enabling more accurate analysis of temperature-related slope changes. As a result, by selecting a specific frequency band, the battery management device minimizes noise or errors caused by SOC changes and can measure and estimate the temperature-related slope changes more accurately.

The battery management device can calculate correlation coefficients between the impedance and SOC. The Pearson correlation coefficient can be used for correlation coefficient calculation. The battery management device selects the frequency band with the smallest absolute value of the correlation coefficient. The impedance measured in this band is minimally affected by SOC changes, thereby improving the accuracy of internal temperature estimation. In the selection process, the battery management device may also consider other factors rather than merely selecting the band with the lowest correlation coefficient. For example, the battery management device may preferentially select a frequency band that also satisfies the condition of minimizing error indices determined in step 2f-S650.

According to one embodiment, in step 2f-S640, the battery management device can create a dataset from at least two of the slope, internal temperature, and SOC. The battery management device acquires the slope values of the graph calculated in each frequency band from the Nyquist plot. The battery management device matches the collected slope values with the corresponding internal temperature to generate data points. By collecting these data points, the battery management device compiles a single dataset.

According to one embodiment, in step 2f-S650, the battery management device can select a specific frequency band that minimizes an error index. The battery management device first uses the dataset created for each frequency band to generate a first learning model for internal temperature estimation. This model uses the graph slope by frequency band as input and outputs the internal temperature. The model can use linear regression, polynomial regression, or machine learning techniques. To evaluate the performance of the first learning model, the battery management device calculates error indices, such as RMSE or MAE (Mean Absolute Error). RMSE is obtained by squaring the difference between the predicted and actual values, averaging them, and taking the square root. MAE is the average of the absolute differences between the predicted and actual values.

Beyond simply selecting the band with the minimum error, the battery management device can also consider stability and consistency. For example, the battery management device may prefer a frequency band that consistently shows low errors.

FIG. 2g is a flowchart illustrating the operation of calculating the X-intercept value by the battery management device according to an embodiment of the present disclosure.

Referring to FIG. 2g, in step 2g-S710, the battery management device can divide the entire frequency range into multiple sections. The battery management device can use various frequencies from mHz to kHz and select an appropriate range according to battery characteristics. Within the set frequency range, the battery management device applies small amplitude AC signals at various frequencies sequentially. At each frequency, it measures the battery's voltage and current response and also measures the phase difference. Based on the measured voltage and current data, the battery management device calculates the impedance at each frequency and stores it by frequency.

According to one embodiment, in step 2g-S720, the battery management device can specify the section where the imaginary part sign change occurs. The battery management device can identify the section where the imaginary part sign change of the impedance occurs. The battery management device measures the impedance at the representative frequency of each section and checks the sign of the imaginary part of the measured impedance. By identifying the section containing the sign change, the battery management device determines the frequency range that needs analysis.

According to one embodiment, in step 2g-S730, the battery management device can identify the first frequency and second frequency at which the sign of the impedance imaginary part changes. The battery management device measures impedance by changing frequencies. Through this process, it identifies two adjacent frequencies at which the sign of the imaginary part changes from negative to positive or vice versa.

According to one embodiment, in step 2g-S740, the battery management device can calculate a first linear equation using the real and imaginary parts of the impedance. The battery management device uses the impedance values at the identified first and second frequencies. By obtaining the equation of the straight line passing through the two points, on a coordinate plane where the real part of the impedance is the x-axis and the imaginary part is the y-axis, the first linear equation is derived. This linear equation can be expressed as y=ax+b, where a is the slope and b is the y-intercept.

According to one embodiment, in step 2g-S750, the battery management device can calculate the X-intercept value using the first linear equation. By substituting y=0 into the linear equation obtained above, the battery management device solves for x, obtaining the X-intercept value.

FIG. 2h is a diagram illustrating the impedance characteristics of the first battery channel at a first SOC according to an embodiment of the present disclosure, FIG. 2i is a diagram illustrating the impedance characteristics of the first battery channel at a second SOC, and FIG. 2j is a diagram illustrating the impedance characteristics of the first battery channel at a third SOC.

FIG. 2h is a diagram illustrating the impedance characteristics of the first battery channel at SOC 10% according to an embodiment of the present disclosure. The graph is a Nyquist plot, where the x-axis represents the real part of the impedance (Zre) and the y-axis represents the negative imaginary part of the impedance (−Zim). Changes in impedance characteristics with temperature variations can be confirmed, and points representing each temperature are distributed according to frequency bands. At SOC 10%, the graph shows a type with no X-intercept, and the internal temperature can be estimated through slope changes in a specific frequency band.

FIG. 2i is a diagram illustrating the impedance characteristics of the first battery channel at SOC 50% according to an embodiment of the present disclosure. Similar to the SOC 10% graph, the x-axis represents Zre and the y-axis represents −Zim, showing impedance characteristics at various temperatures. At SOC 50%, the graph also shows a type without an X-intercept, and the internal temperature can be estimated through slope changes in a specific frequency band.

FIG. 2j is a diagram illustrating the impedance characteristics of the first battery channel at SOC 90% according to an embodiment of the present disclosure. As with the SOC 10% and SOC 50% graphs, the x-axis represents Zre and the y-axis represents-Zim. The impedance characteristics at various temperatures can be confirmed. At SOC 90%, the graph also shows a type without an X-intercept, and the internal temperature can be estimated through slope changes in a specific frequency band.

In FIGS. 2h to 2j, the specific frequency band section is indicated by a box, and this frequency band is approximately between 1 kHz and 125 Hz. By analyzing slope changes in this frequency band, the internal temperature of the battery can be estimated, showing consistent results with the SOC 10% and SOC 50% graphs. The specific frequency band can be first selected to minimize the influence of slope and SOC, and then secondarily selected after performance evaluation of the learning model trained for the correlation between slope and internal temperature.

FIG. 2k is a diagram illustrating the impedance characteristics of the first battery channel at SOC 10% in a specific frequency band according to an embodiment of the present disclosure; FIG. 2l is a diagram illustrating the impedance characteristics of the first battery channel at SOC 50% in a specific frequency band; and FIG. 2m is a diagram illustrating the impedance characteristics of the first battery channel at SOC 90% in a specific frequency band according to an embodiment of the present disclosure.

FIG. 2k is a diagram illustrating the impedance characteristics of the first battery channel at SOC 10% in a specific frequency band according to an embodiment of the present disclosure. This graph is a Nyquist plot with Zre on the x-axis and −Zim on the y-axis. Each data point represents the impedance measured at various temperatures from −10° C. to 60° C. Each line in the graph represents impedance data at a specific temperature, and the slope of the line shows the impedance characteristics at that temperature. For example, the slope at −10° C. is about −0.17, and the slope at 60° C. is about −1.57. These slope values can be used to estimate the internal temperature of the battery by utilizing their linear relationship with the internal temperature.

FIG. 2l is a diagram illustrating the impedance characteristics of the first battery channel at SOC 50% in a specific frequency band according to an embodiment of the present disclosure. The graph has the same format as SOC 10%, with Zre on the x-axis and −Zim on the y-axis. Each data point represents impedance measured at various temperatures from −10° C. to 60° C., and slope values at each temperature are included. For example, at −10° C. the slope is about −0.21, and at 60° C. the slope is about −1.48. Such slope values can be used to estimate the internal temperature of the battery, clearly showing impedance characteristics corresponding to temperature changes.

FIG. 2m is a diagram illustrating the impedance characteristics of the first battery channel at SOC 90% in a specific frequency band according to an embodiment of the present disclosure. Similarly, the x-axis is Zre, the y-axis is −Zim, and the impedance data measured at various temperatures is included. Each temperature has a slope value, for example, about −0.2 at −10° C. and about −1.6 at 60° C. These slope values can be used to estimate the internal temperature of the battery at SOC 90%, clearly identifying the impedance characteristics varying with temperature.

The battery management device can also estimate the internal temperature from the slope regardless of SOC by using a second learning model that has learned the relationship between slope and internal temperature in a specific frequency band that minimizes the correlation between SOC and the slope.

FIG. 2n is a diagram illustrating the impedance characteristics of the second battery channel at SOC 10% according to an embodiment of the present disclosure, FIG. 20 is a diagram illustrating the impedance characteristics of the second battery channel at SOC 50%, and FIG. 2p is a diagram illustrating the impedance characteristics of the second battery channel at SOC 90%.

FIG. 2n is a diagram illustrating the impedance characteristics of the second battery channel at SOC 10% according to an embodiment of the present disclosure. This graph is a Nyquist plot with Zre on the x-axis and −Zim on the y-axis. Points representing each temperature are distributed according to frequency bands, visualizing impedance changes with temperature. At SOC 10%, the graph shows a type with an X-intercept, reflecting the electrolyte resistance.

FIG. 20 is a diagram illustrating the impedance characteristics of the second battery channel at SOC 50% according to an embodiment of the present disclosure. As with SOC 10%, Zre is on the x-axis and −Zim is on the y-axis, and the impedance characteristics at various temperatures are shown. At SOC 50%, the graph also shows a type with an X-intercept, reflecting the temperature-dependent frequency response characteristics.

FIG. 2p is a diagram illustrating the impedance characteristics of the second battery channel at SOC 90% according to an embodiment of the present disclosure. Similarly to SOC 10% and SOC 50%, Zre is on the x-axis and −Zim is on the y-axis. Temperature-dependent impedance characteristics can be confirmed, and at SOC 90%, the graph shows a type with an X-intercept. The battery management device can calculate the X-intercept value and estimate the internal temperature of the battery.

The Arrhenius linear equation according to the present disclosure can refer to an equation representing the relationship between temperature and chemical reaction rate. Specifically, the Arrhenius linear equation may indicate that the collected impedance parameters are expressed as a linear equation by converting them into natural logarithms and converting the temperature data into the reciprocal of the absolute temperature.

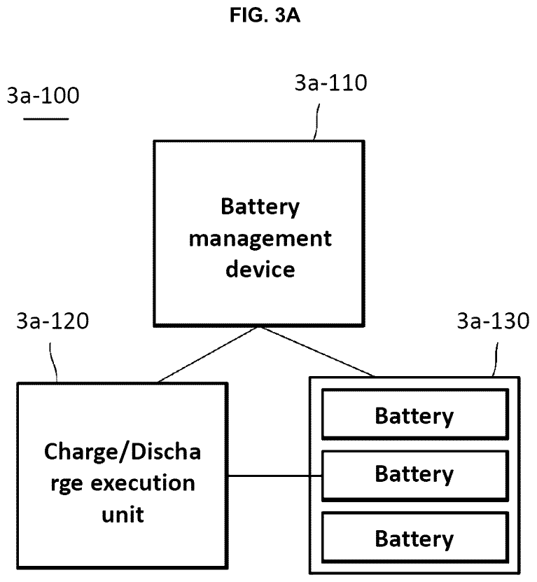

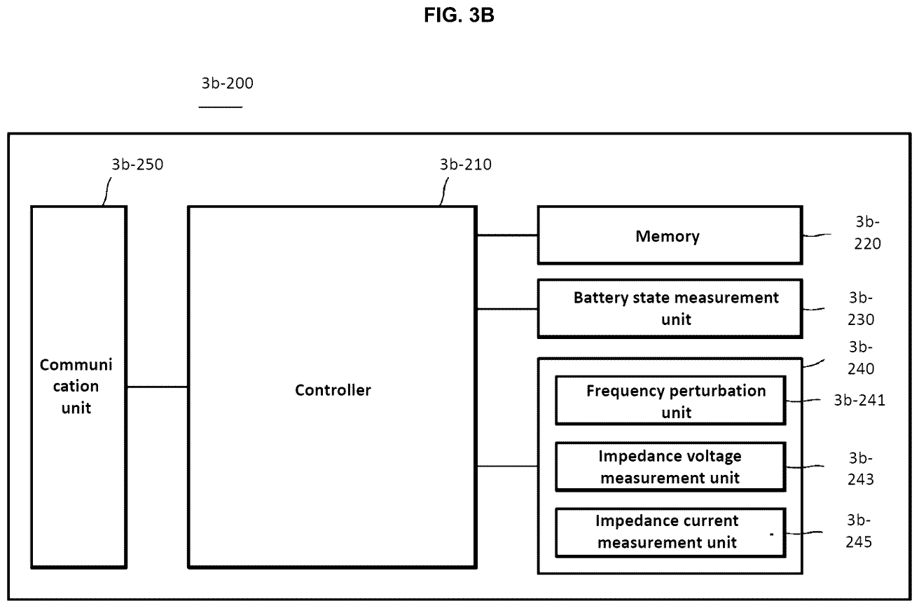

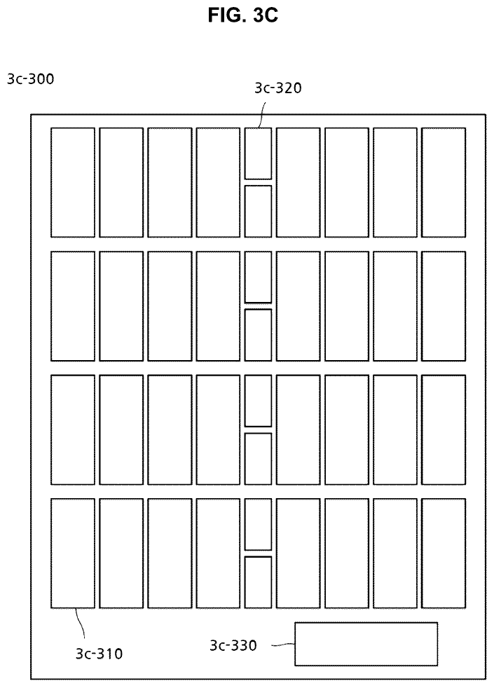

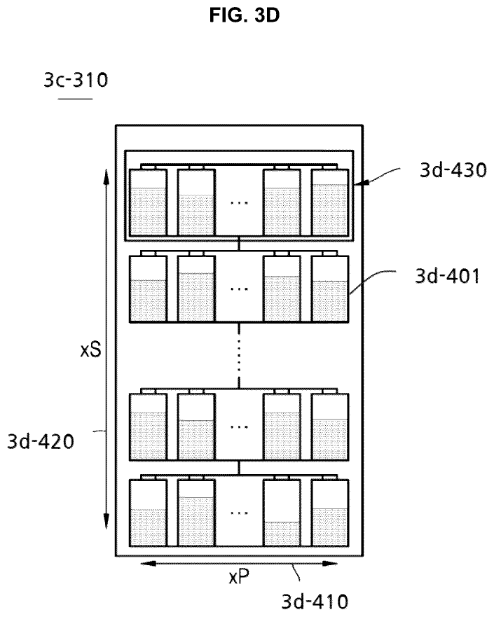

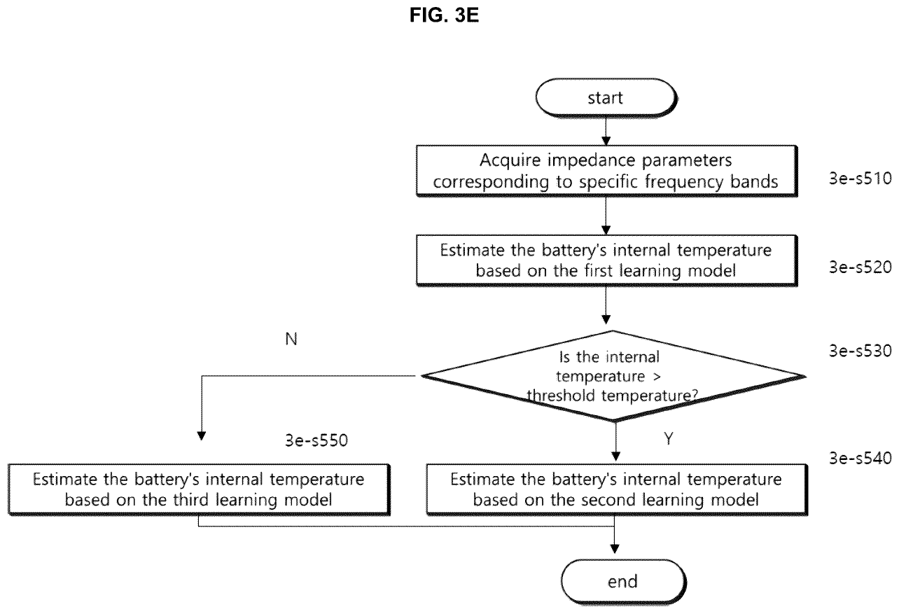

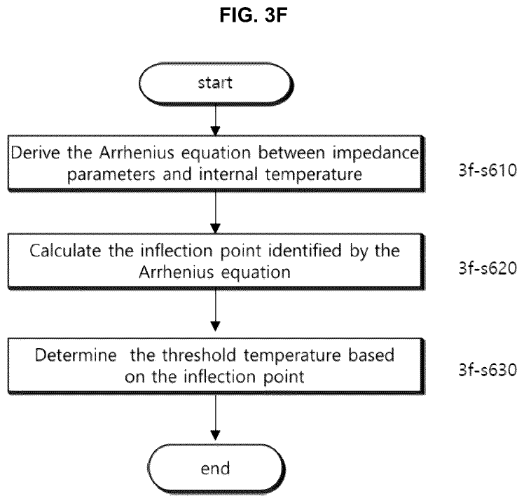

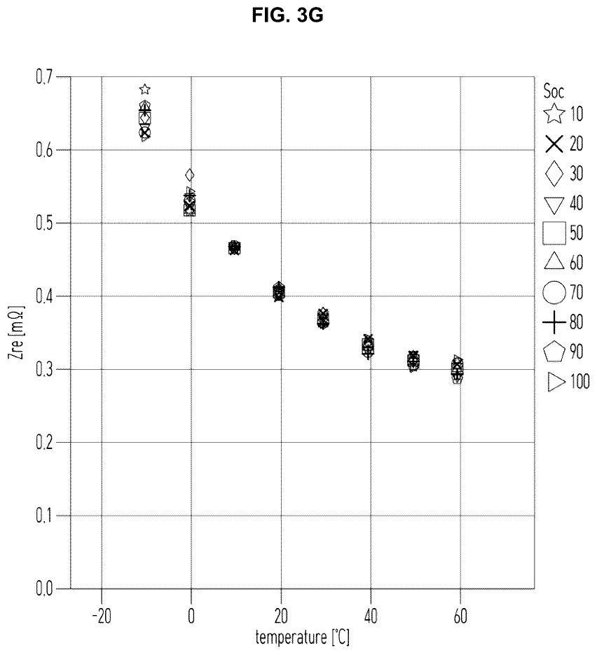

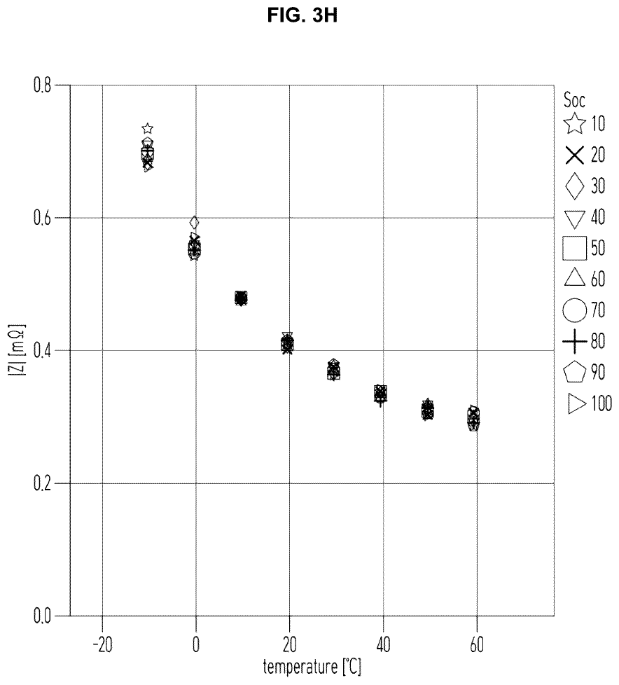

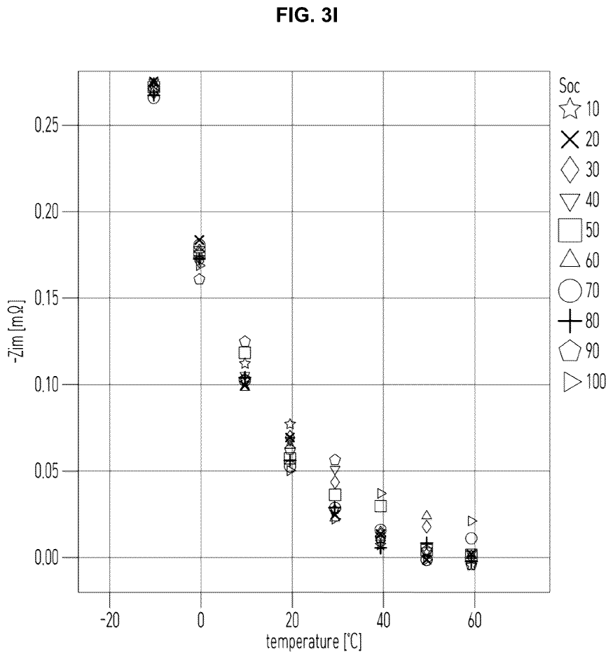

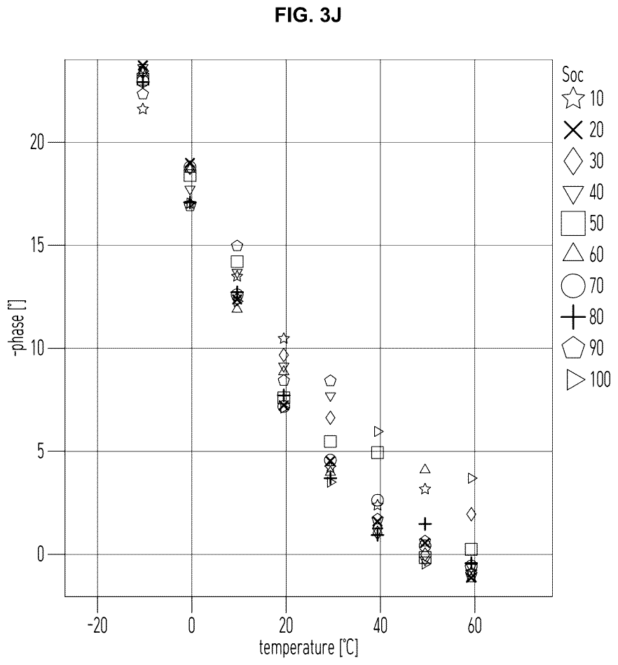

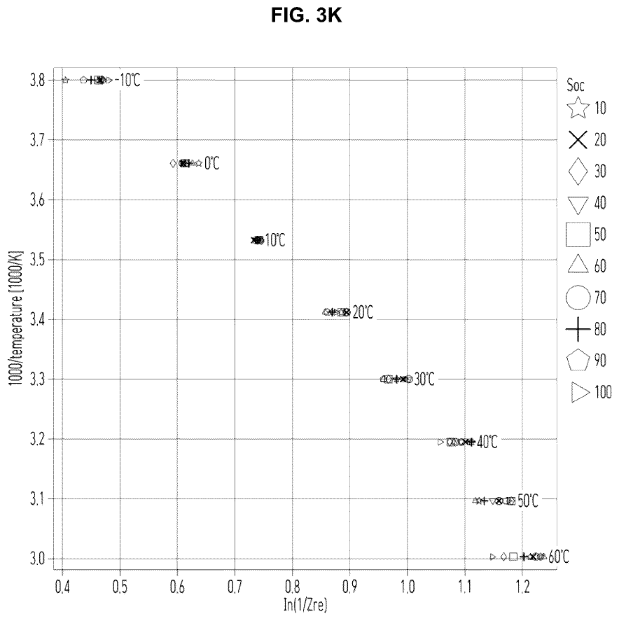

FIG. 3a is a diagram schematically illustrating a management system (3a-100) according to one embodiment of the present disclosure.

Referring to FIG. 3a, the management system (3a-100) may include a Battery management system (BMS) (3a-110), a Charge/Discharge execution unit (3a-120), and a plurality of batteries (3a-130).

The plurality of batteries (3a-130) are devices subject to internal temperature and fire prediction. They may be charged or discharged while connected to the Charge/Discharge execution unit (3a-120) and may be managed while connected to the Battery management device (3a-110).

The Charge/Discharge execution unit (3a-120) may be controlled by the Battery management device (3a-110) to perform charging or discharging for the connected batteries (3a-130).

The Battery management device (3a-110) is a device that controls charging and discharging of the batteries, and may perform battery state of charge (SOC) estimation and battery state monitoring. Specifically, the Battery management device (3a-110) may measure current of the battery (3a-130) mounted on an Energy Storage System (ESS), an electric vehicle (BEV), etc., measure cell voltage, measure surface temperature, estimate SOC, perform cell balancing, control relays or FETs, diagnose failures, and predict fires.

According to one embodiment of the present disclosure, the Battery management device (3a-110) may estimate the internal temperature of the battery (3a-130) and perform fire diagnosis and fire management. Such a Battery management device (3a-110) may perform operations according to one embodiment of the present disclosure. Hereinafter, the Battery management device (3a-110) will be described in detail with reference to FIG. 3b.

The management system (3a-100) according to one embodiment of the present disclosure may further include a separate server (not shown). For example, the server may include a plurality of set equivalent circuit models. The Battery management device (3a-110) may transmit information on the impedance of the battery (3a-130) to the server and receive information on the internal temperature of the battery from the server to manage the battery (3a-130).

FIG. 3b is a diagram schematically illustrating the configuration (3b-200) of the Battery management device (3a-110) according to one embodiment of the present disclosure.

Referring to FIG. 3b, the Battery management device (3a-110) is illustrated as being composed of a Controller (3b-210), a Memory (3b-220), a Battery state measurement unit (3b-230), an Impedance measurement unit (3b-240), and a Communication unit (3b-250), but is not necessarily limited thereto. For example, the Controller (3b-210), the Memory (3b-220), the Battery state measurement unit (3b-230), the Impedance measurement unit (3b-240), and the Communication unit (3b-250) may each exist as physically independent components.

The Memory (3b-220) may store various data for the overall operation of the Battery management device (3a-110), such as programs for processing or control by the Controller (3b-210) in the Battery management device (3a-110). The Memory (3b-220) may store multiple application programs, data for the operation of the Battery management device (3a-110), and instructions. The Memory (3b-220) may be implemented as an internal memory such as ROM or RAM included in the Controller (3b-210), or as a memory separate from the Controller (3b-210).

According to one embodiment, the Memory (3b-220) may store a plurality of set equivalent circuit models, current of the battery (3a-130), cell voltage, surface temperature, SOC, and the like. The Memory (3b-220) may be implemented as an internal memory included in the Controller (3b-210) or as a separate external memory.

The Battery state measurement unit (3b-230) may measure the voltage of the battery cell, perform cell balancing, and measure the surface temperature of the battery cell. The Battery state measurement unit (3b-230) may measure the voltage of the battery cell, perform cell balancing, measure the internal temperature and surface temperature, and deliver that data to the Controller (3b-210).

The Impedance measurement unit (3b-240) may measure the impedance of the battery in each frequency band. The Impedance measurement unit (3b-240) may be implemented by a Frequency perturbation unit (3b-241), an Impedance voltage measurement unit (3b-243), and an Impedance current measurement unit (3b-245). The Impedance measurement unit (3b-240) may measure the impedance of the battery using Electrical Impedance Spectroscopy (EIS). Specifically, the Impedance measurement unit (3b-240) may apply infinitesimal sinusoidal current and voltage signals ranging from the high-frequency region to the low-frequency region within a range that does not deviate from the electrical and thermal equilibrium states of the battery. By measuring the changes in amplitude and phase through the responded impedance voltage and impedance current signals, the Impedance measurement unit (3b-240) may analyze the impedance. The Impedance measurement unit (3b-240) may apply a frequency band instructed by the Controller (3b-210) to the battery (3a-130) to analyze the impedance and deliver at least one of the impedance voltage, impedance current, and impedance to the Controller (3b-210). The measurement unit may extract necessary signals for impedance voltage and current through passive and active filters. The filter function of the measurement unit may be configured by ICs, OPAMPs, and RLC components or may be implemented by an MCU and RLC components. After passing through the filter, the values may be transferred to the ADC (analog-to-digital converter) of the controller. The Impedance measurement unit (3b-240) may be implemented so that one or more processors perform its functions.

The Frequency perturbation unit (3b-241) may apply a frequency signal to the battery to measure the impedance of the battery in each frequency band. The Frequency perturbation unit (3b-241) may apply sinusoidal current and voltage signals corresponding to the frequency band instructed by the Controller (3b-210).

The Impedance voltage measurement unit (3b-243) may measure the impedance voltage of the battery perturbed by the Frequency perturbation unit (3b-241). The Impedance voltage measurement unit (3b-243) may measure the voltage applied to the battery by the signals applied by the Frequency perturbation unit (3b-241).

The Impedance current measurement unit (3b-245) may measure the impedance current of the battery perturbed by the Frequency perturbation unit (3b-241). The Impedance current measurement unit (3b-245) may measure the current flowing through the battery by the signals applied by the Frequency perturbation unit (3b-241).

The Communication unit (3b-250) may perform functions for transmitting and receiving signals through a network.

All or part of the Communication unit (3b-250) may be referred to as a transmitter, a receiver, or a transceiver. The Communication unit (3b-250) may provide functions for communication between the Battery management device (3a-110) and at least one other node through a communication network. According to one embodiment of the present disclosure, when a request signal is generated according to program code stored in a recording device such as the Memory (3b-220) of the Battery management device (3a-110), the request signal may be transmitted to at least one other node through the communication network under the control of the Communication unit (3b-250). Conversely, control signals, commands, contents, or files provided under the control of at least one other node's processor may be received by the Battery management device (3a-110) through the Communication unit (3b-250). According to one embodiment, the Communication unit (3b-250) may transmit impedance information to the server and receive internal temperature information of the battery from the server.

The Controller (3b-210) may be a component for generally controlling the Battery management device (3a-110).

The Controller (3b-210) may control the Impedance measurement unit so that a signal in a specific frequency band is applied to the battery. The Controller (3b-210) may receive impedance parameters corresponding to a specific frequency band from the Impedance measurement unit. In addition, the Controller (3b-210) may input these impedance parameters to a first learning model to estimate the internal temperature of the battery.

If the internal temperature of the battery estimated by the first learning model exceeds a critical temperature, the Controller (3b-210) may input the impedance parameters to a second learning model to re-estimate the internal temperature. Conversely, if the internal temperature is below the critical temperature, the Controller (3b-210) may input the impedance parameters to a third learning model to re-estimate the internal temperature.

The Controller (3b-210) may process the impedance parameters of the battery to include at least one of the real part, the imaginary part, magnitude, and phase of the impedance. Through this, the accuracy of the battery management system can be improved and the safety of the battery can be ensured.

Further, the Controller (3b-210) may measure impedance by frequency band for each battery cell included in a battery module having a plurality of battery cells and estimate the internal temperature of each individual battery cell. The estimated data may be utilized in the Battery management device, thereby improving the overall performance and safety of the battery pack.

Specifically, the Controller (3b-210) may control the operation of the Battery management device (3a-110) using various programs stored in the Memory (3b-220) of the Battery management device (3a-110). The Controller (3b-210) may include a CPU, RAM, ROM, system bus, etc. The Controller (3b-210) may be implemented as a single CPU or multiple CPUs (or DSP, SOC). In one embodiment, the Controller (3b-210) may be implemented as a digital signal processor (DSP), a microprocessor, or a TCON (Time controller) that processes digital signals. However, the implementation is not limited thereto and may be defined by including one or more of a central processing unit (CPU), an MCU (Micro Controller Unit), an MPU (micro processing unit), a controller, an application processor (AP), or a communication processor (CP), or by these terms. Also, the Controller (3b-210) may be implemented as a System on Chip (SOC) or LSI (large scale integration) with embedded processing algorithms, or in the form of an FPGA (Field Programmable Gate Array).

According to one embodiment, the Controller (3b-210) may control the Impedance measurement unit (3b-240) to apply a frequency band signal to the battery. The Controller (3b-210) may receive the impedance voltage and impedance current from the Impedance measurement unit (3b-240) and calculate the impedance using the digital lock-in amplifier principle. Also, the Controller (3b-210) may receive the impedance from the Impedance measurement unit (3b-240). The impedance may be represented by real and imaginary parts, and the Controller (3b-210) may calculate the magnitude and phase of the impedance. Further, the Controller (3b-210) may transmit and receive the impedance voltage and impedance current values through the Communication unit (3b-250) to/from an external server or cloud, and the external server or cloud may calculate the impedance using the digital lock-in amplifier principle.

According to one embodiment, the Controller (3b-210) may acquire impedance data by frequency band of the battery from the Impedance measurement unit (3b-240). The Controller (3b-210) and the Impedance measurement unit (3b-240) may be directly connected via a data bus, so that the measured impedance data can be received in real time. The impedance data may be distinguished by frequency and include magnitude and phase of impedance for each frequency, or include the real and imaginary parts of impedance. The Controller (3b-210) may temporarily store the received data in an internal memory or store it long-term in the Memory (3b-220).

FIG. 3c is a diagram schematically illustrating a battery pack according to one embodiment of the present disclosure.

FIG. 3c schematically illustrates a battery pack (3c-300) according to one embodiment of the present disclosure. FIG. 3c may include a plurality of battery modules (3c-310), a Battery Management Unit (BMU) (3c-330), and a Cell Monitoring Unit (CMU) (3c-320) as a battery management system having a plurality of battery modules and a plurality of channels.

FIG. 3c may correspond to a part of the configuration of FIG. 3a. For example, the battery module (3c-310) may be composed of a plurality of batteries (3a-130), and the battery module (3c-310) will be described in detail below. A plurality of CMUs (3c-320) and a plurality of BMUs (3c-330) may be combined to perform at least one operation of the Battery management device (3a-110).

The CMU (3c-320) may monitor and manage battery cells. It may measure the voltage, temperature, and impedance of each battery cell and provide data to the BMU (3c-330). The CMU (3c-320) manages the battery module. For example, a single CMU (3c-320) may manage two to eight battery modules (3c-310).

The BMU (3c-330) may monitor and manage the state of the entire battery system. It may receive data from each of the plurality of CMUs (3c-320) and estimate the overall State Of Charge (SOC) and State Of Health (SOH) of the entire battery pack. In addition, the BMU (3c-330) may protect the battery in situations such as overcharge, overdischarge, and overheating. Specifically, the BMU (3c-330) may determine a frequency band for each multi-module and multi-channel or measure a set impedance value in the frequency band to perform internal temperature estimation of the battery.

FIG. 3d is a diagram schematically illustrating a battery module according to one embodiment of the present disclosure. Referring to FIG. 3d, a single battery module (3c-310) may include a plurality of battery cells (3a-1001). Specifically, the battery module (3c-310) may have battery cells (3d-401) connected in series and parallel. For example, a battery module (3c-310) in which Battery cells connected in parallel-xP (3d-410) are connected in parallel and Battery cells connected in series-xS (3d-420) are connected in series may be indicated as an xP xS battery module, and such a series connection unit of battery cells (3d-401) may be called a channel (3d-430). For example, in a 2P6S battery module (3c-310), there may be a total of 6 channels. When there are a plurality of such battery modules (3c-310), it may be referred to as a multi-module, multi-channel battery system.

According to one embodiment of the present disclosure, the Battery management device may estimate the battery state or the internal temperature of the battery with respect to at least one of the battery module (3c-310), the channel (3d-430), and the battery cell (3d-401).

FIG. 3e is a flowchart illustrating the operation of estimating the internal temperature of a battery by the Battery management device according to one embodiment of the present disclosure.

Referring to FIG. 3e, in step 3e-S510, the Battery management device may control to apply a signal in a specific frequency band to the battery, receive an impedance parameter corresponding to the specific frequency band, and obtain the impedance parameter. The Battery management device may apply an AC signal of a specific frequency band to the battery. This signal induces electrochemical reactions inside the battery, and these reactions may vary depending on the state and characteristics of the battery. The Battery management device may measure the impedance of the battery through frequency response analysis. The Battery management device may extract impedance parameters based on the measured voltage and current changes. The impedance parameter may include at least one of a real part, an imaginary part, magnitude, and phase.

According to one embodiment of the present disclosure, in step 3e-S520, the Battery management device may input the impedance parameter into a first learning model to estimate the internal temperature of the battery. The first learning model is a model that has learned the relationship between the impedance parameter and the internal temperature of the battery and may be a regression model based on the Arrhenius linear equation. The Battery management device may input the impedance parameter into the model and estimate the internal temperature of the battery from the output.

For example, the impedance parameter (Z) may be transformed into In (1/Z). For instance, if the real part of the impedance is R, then the transformed value may be In (1/R). For the temperature (T), the value 3a-1000/T(K) may be used. For example, 25° C. is 298.15K, and the transformed value is about 3.35. When the transformed impedance value (Y-axis) and the transformed temperature value (X-axis) are plotted, a linear relationship is shown. This linear relationship can be expressed as In (1/Z)=a*(3a-1000/T)+b, where a is the slope and b is the y-intercept. Using this equation, when an impedance measurement value is given, the temperature can be estimated. If the measured impedance is Z_measured, the temperature T can be calculated as T=3a-1000/((In(1/Z_measured)−b)/a).

The Battery management device may apply different linear equations depending on whether the temperature is below or above a critical temperature (e.g., 40° C.), since the relationship between impedance and temperature may differ. By using two different linear equations (with different a and b values) for temperatures below and above the critical temperature, more accurate temperature estimation can be achieved. The linear regression coefficients (a, b) can be determined using actual data and methods such as least squares.

According to one embodiment of the present disclosure, in step 3e-S530, the Battery management device may compare the estimated internal temperature with a critical temperature. This critical temperature may be set as the temperature at which the slope according to the Arrhenius linear equation for impedance parameters and internal temperature is distinguished. For example, if 40° C. is identified as the inflection point at which the slope changes, the critical temperature may be set to 40° C. The Battery management device may compare the estimated internal temperature value with the critical temperature value. If the estimated internal temperature exceeds the critical temperature, the Battery management device may proceed to step 3e-S540. If the estimated internal temperature is below the critical temperature, the Battery management device may proceed to step 3e-S550.

If the estimated internal temperature exceeds the critical temperature, the Battery management device proceeds to step 3e-S540 to input the impedance parameter into a second learning model to re-estimate the internal temperature of the battery.

If, in step 3e-S520, the estimated internal temperature exceeds the critical temperature, the Battery management device may input the impedance parameter into the second learning model to re-estimate the internal temperature of the battery. In this process, the impedance parameters obtained in step 3e-S510 may be used. The impedance parameter may include at least one of the real part, imaginary part, magnitude, and phase. The Battery management device may input the impedance parameter into the second learning model. The second learning model may be a model related to the internal temperature range exceeding the critical temperature. Specifically, this model may be generated based on a data set including impedance parameters and internal battery temperatures above the critical temperature. In this process, the Arrhenius linear equation may be utilized. The impedance parameter may be transformed into In (1/parameter), and the temperature may be transformed into 3a-1000/absolute temperature and then input into the model to linearize the nonlinear relationship between impedance and temperature.

If the estimated internal temperature is below the critical temperature, the Battery management device proceeds to step 3e-S550 to input the impedance parameter into a third learning model to re-estimate the internal temperature of the battery. In this case, the impedance parameters obtained in step 3e-S510 may be utilized. The impedance parameter may include at least one of the real part, imaginary part, magnitude, and phase.

The impedance parameter may be input into the third learning model. The third learning model may be related to the internal temperature range below the critical temperature. Specifically, this model may be generated based on a data set including impedance parameters and internal battery temperatures below the critical temperature. The Arrhenius linear equation may be utilized in this process. The impedance parameter may be transformed into In (1/parameter) and the temperature into 3a-1000/absolute temperature, and then input into the model to linearize the relationship between impedance and temperature.

The first learning model, the second learning model, and the third learning model may be generated as follows. The Battery management device may collect impedance parameters and internal temperature data over the entire temperature range. The Battery management device may train a regression model based on the Arrhenius linear equation using the collected data. The Battery management device may generate the first learning model, which takes impedance parameters as input and outputs internal temperature. This device uses the first learning model for approximate internal temperature estimation over the entire temperature range.

The Battery management device may select only data above the critical temperature. It may train a separate regression model, the second learning model, using the selected high-temperature region data. By more accurately modeling the relationship between impedance parameters and internal temperature in the high-temperature region, the device can improve the accuracy of internal temperature estimation in that region.

The Battery management device may select only data below the critical temperature. It may train another regression model, the third learning model, using the selected low-temperature region data. By more accurately modeling the relationship between impedance parameters and internal temperature in the low-temperature region, the device can improve the accuracy of internal temperature estimation in that region.

The Battery management device may analyze the correlation between impedance parameters and SOC at each frequency. Using Pearson correlation coefficients or other statistical methods, the Battery management device may quantify this correlation and select a frequency band that minimizes the correlation between impedance parameters and SOC. The Battery management device may use the impedance data at the selected frequency to train the internal temperature estimation model and evaluate its performance. If the error index is below a threshold, that frequency band may be determined as the specific frequency band.

FIG. 3f is a flowchart illustrating the operation of determining the critical temperature by the Battery management device according to one embodiment of the present disclosure.

Referring to FIG. 3f, in step 3f-S610, the Battery management device may derive the Arrhenius linear equation between the impedance parameter and the internal temperature. The Battery management device may measure the impedance of the battery under various temperature conditions. To do this, it may apply an AC signal of a certain frequency band (for example, 79.5 Hz) to the battery and measure the response. The measured impedance may be represented by parameters such as real part, imaginary part, magnitude, and phase. The internal temperature of the battery may be measured directly or indirectly using a thermocouple. The Battery management device may convert the measured impedance parameters into a form suitable for the Arrhenius equation. For example, if using the real part of the impedance, In (1/real part) may be used. The internal temperature may be converted into Kelvin and then transformed into the form 3a-1000/T(K). The Battery management device may represent the preprocessed data on a graph, placing the transformed impedance parameter on one axis and the transformed temperature on the other axis.

According to one embodiment of the present disclosure, in step 3f-S620, the Battery management device may derive an inflection point at which the slope according to the Arrhenius linear equation is distinguished. The Battery management device may divide the entire dataset obtained in step 3f-S610 into multiple sections. It may do so by dividing the temperature range at regular intervals or based on the number of data points. The Battery management device may perform linear regression analysis on each divided section. It may calculate the slope and y-intercept for each section. The Battery management device may compare the slopes of each section and analyze changes in slope. It may identify points where the slope changes abruptly. In addition, the Battery management device may apply continuous differentiation to the entire data to calculate the rate of change of slope. Through this, the device may find the point where the slope changes the most. The Battery management device may test the statistical significance of the slope difference between adjacent sections using t-tests, F-tests, or other statistical methods.

The Battery management device may visually check the slope change and estimate the inflection point by plotting the scatter plot of the entire data and drawing regression lines for each section. The Battery management device may try various division points and find the point that minimizes the overall model error through iterative calculation and comparison.

According to one embodiment of the present disclosure, in step 3f-S630, the Battery management device may determine the critical temperature based on the inflection point. The Battery management device may confirm the x and y coordinates of the inflection point calculated in step 3f-S620. These coordinates represent the transformed impedance parameter value and transformed temperature value. The Battery management device may inverse transform the y coordinate (transformed temperature value) back to the original temperature unit. For example, if the y coordinate is in the form 3a-1000/T(K), the Battery management device may perform T=3a-1000/y and convert the Kelvin temperature back to Celsius. The Battery management device may set the inverse-transformed temperature value as the initial value of the critical temperature. This value represents the temperature at which the slope of the Arrhenius linear equation changes. The Battery management device may establish multiple levels of critical temperature if necessary. It may periodically re-evaluate the critical temperature to determine if adjustment is needed due to battery aging or changes in usage patterns.

FIG. 3g is a diagram showing the real part of the impedance according to temperature for each SOC according to one embodiment of the present disclosure. FIG. 3h is a diagram showing the magnitude of the impedance according to temperature for each SOC according to one embodiment of the present disclosure. FIG. 3i is a diagram showing the imaginary part of the impedance according to temperature for each SOC according to one embodiment of the present disclosure, and FIG. 3j is a diagram showing the phase of the impedance according to temperature for each SOC according to one embodiment of the present disclosure.

Referring to FIGS. 3g to 3j, the SOC (State of Charge) values are indicated by different points. Each figure shows how impedance parameters change with temperature and SOC. In comparison, among the impedance parameters, the real part and magnitude remain relatively constant with temperature at each SOC level or do not differ significantly with changes in SOC, unlike the imaginary part and phase.

FIG. 3k is a diagram showing the temperature according to the real part of the impedance based on the Arrhenius linear equation for each SOC according to one embodiment of the present disclosure. The x-axis represents the natural log value of the reciprocal of the real part (Zre) of the impedance. According to the Arrhenius law, this is used to analyze the change in electrochemical reaction rates according to temperature. As the real part of the impedance decreases, the temperature increases. The y-axis represents the value obtained by multiplying the reciprocal of the temperature by 3a-1000. As the temperature decreases, the y-axis value becomes larger, and as the temperature increases, the value becomes smaller.

Referring to FIG. 3k, data points are shown for the relationship between the real part of the impedance and temperature measured at various SOC values. Each SOC is distinguished by a different color, and this data represents the distribution of SOC at a specific temperature.

As described above, although the embodiments have been described with reference to limited embodiments and drawings, those skilled in the art will appreciate that various modifications and changes are possible from the above description. For example, the described techniques may be performed in an order different from the described method, and/or the elements of systems, structures, devices, circuits, etc. described herein may be combined or integrated in other ways or replaced or substituted by other elements or equivalents to achieve suitable results. In other embodiments consistent with the principles of the present disclosure, the order of operations may be changed. Non-dependent operations may be executed in parallel.

Therefore, other implementations, embodiments, and equivalents that are consistent with the principles of the present disclosure also belong to the scope of the claims described below.

What is claimed is:

1. A battery management device comprising:
an impedance measurement unit configured to measure impedance data of a battery for each frequency band; and
a controller configured to acquire the frequency-band-specific impedance data measured by the impedance measurement unit, generate a graph representing impedance characteristics of the battery based on the impedance data, identify whether the graph is of a type having an X-intercept, and, if the graph is of a type having no X-intercept, calculate a slope of the graph in a specific frequency band and estimate an internal temperature of the battery using a first trained model that has learned a correlation between the slope and the internal temperature.

2. The battery management device of claim 1, wherein the controller selects the specific frequency band that minimizes correlation between a State of Charge (SOC) and the slope, and that minimizes an error index of the first trained model, and calculates the slope in the selected frequency band.

3. The battery management device of claim 2, wherein the first trained model is a model trained using a training dataset including the slope of the graph in the specific frequency band and the internal temperature.

4. The battery management device of claim 1, wherein the controller estimates the internal temperature using a polynomial regression model, and an order of the polynomial regression model is determined through performance evaluation.

5. The battery management device of claim 1, wherein the graph representing the impedance characteristics is a Nyquist plot.

6. The battery management device of claim 1, wherein if the graph representing the impedance characteristics is of a type having an X-intercept, the controller calculates an X-intercept value and estimates the internal temperature using a second trained model that has learned a correlation between the X-intercept value and the internal temperature.

7. The battery management device of claim 6, wherein the controller identifies a first frequency and a second frequency at which a sign of an imaginary part of the impedance changes, derives a first-order linear equation using real and imaginary parts of the impedance corresponding to the two frequencies, and calculates the X-intercept value using the first-order linear equation.

8. The battery management device of claim 7, wherein the controller divides an entire frequency range into a plurality of sections, measures impedance at a representative frequency of each section to identify a section in which a sign of the imaginary part changes, and thereafter performs measurements within the identified section to identify the first frequency and the second frequency.

9. A battery pack comprising:
a battery module having a battery channel including a plurality of battery cells; and
a battery management device including:
an impedance measurement unit configured to measure impedance data of each battery cell for each frequency band; and
a controller configured to acquire the frequency-band-specific impedance data measured by the impedance measurement unit for each battery channel, generate a graph representing impedance characteristics of the battery based on the impedance data, identify whether the graph is of a type having an X-intercept, and, if the graph is of a type having no X-intercept, calculate a slope of the graph in a specific frequency band and estimate an internal temperature of the battery using a first trained model that has learned a correlation between the slope and the internal temperature.

10. A battery management method comprising:
measuring impedance data of a battery for each frequency band;
obtaining the measured frequency-band-specific impedance data;
generating a graph representing impedance characteristics of the battery based on the obtained impedance data;
identifying a type of the generated graph and determining whether an X-intercept exists;
if the graph is of a type having no X-intercept, calculating a slope of the graph in a specific frequency band; and
estimating an internal temperature of the battery using a first trained model that has learned a correlation between the slope and the internal temperature.

11. The battery management method of claim 10, further comprising, if the graph is of a type having an X-intercept, calculating an X-intercept value and estimating the internal temperature using a second trained model that has learned a correlation between the X-intercept value and the internal temperature.
